(19) United States
(12) Patent Application Publication
(10) Pub. No.: US 2026/0317582 A1
(43) Pub. Date: Oct. 15, 2026

(54) CHEMICAL-MECHANICAL POLISHING COMPOSITION CONTAINING MODIFIED SILICA ABRASIVES AND CATIONIC POLYMER

(71) Applicant: ENTEGRIS, INC., Billerica, MA (US)

(72) Inventors: Yuqing Yang, Naperville, IL (US); Alex Villani-Gale, Chicago, IL (US); Brian Reiss, Woodridge, IL (US); Elliot Knapton, Aurora, IL (US); Hawa Keita, Aurora, IL (US)

(21) Appl. No.: 19/647,281

(22) Filed: Apr. 14, 2026

Related U.S. Application Data
(60) Provisional application No. 63/789,368, filed on Apr. 15, 2025.

(51) Int. Cl. C09G 1/02; B24B 37/04; C09K 3/14; H10P 52/40

(52) U.S. Cl. CPC C09G 1/02; B24B 37/044; C09K 3/1436; H10P 52/403; H10P 52/407

(57) ABSTRACT

The invention provides a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) a cationic polymer, (c) a buffering agent, and (d) water, wherein the polishing composition has a pH of about 1 to about 6. The invention also provides a method of chemically-mechanically polishing a substrate using said composition.

### BACKGROUND OF THE INVENTION

In the fabrication of integrated circuits and other electronic devices, multiple layers of conducting, semiconducting, and dielectric materials are deposited onto or removed from a substrate surface. As layers of materials are sequentially deposited onto and removed from the substrate, the uppermost surface of the substrate may become non-planar and require planarization. Planarizing a surface, or “polishing” a surface, is a process where material is removed from the surface of the substrate to form a generally even, planar surface. Planarization is useful in removing undesired surface topography and surface defects, such as rough surfaces, agglomerated materials, crystal lattice damage, scratches, and contaminated layers or materials. Planarization also is useful in forming features on a substrate by removing excess deposited material used to fill the features and to provide an even surface for subsequent levels of metallization and processing.

Compositions and methods for planarizing or polishing the surface of a substrate are well known in the art. Chemical-mechanical planarization, or chemical-mechanical polishing (CMP), is a common technique used to planarize substrates. CMP utilizes a chemical composition, known as a CMP composition or more simply as a polishing composition (also referred to as a polishing slurry), for selective removal of material from the substrate. Polishing compositions typically are applied to a substrate by contacting the surface of the substrate with a polishing pad (e.g., polishing cloth or polishing disk) saturated with the polishing composition. The polishing of the substrate typically is further aided by the chemical activity of the polishing composition and/or the mechanical activity of an abrasive suspended in the polishing composition or incorporated into the polishing pad (e.g., fixed abrasive polishing pad).

A polishing composition can be characterized according to its polishing rate (i.e., removal rate) and its planarization efficiency. The polishing rate refers to the rate of removal of a material from the surface of the substrate and is usually expressed in terms of units of length (thickness) per unit of time (e.g., Angstroms (Å) per minute). Planarization efficiency relates to step height reduction versus amount of material removed from the substrate. Specifically, a polishing surface, e.g., a polishing pad, first contacts the “high points” of the surface and must remove material in order to form a planar surface. A process that results in achieving a planar surface with less removal of material is considered to be more efficient than a process requiring removal of more material to achieve planarity.

One particular material of interest is polysilicon, which has been widely used in the dielectric market. However, commercially available chemical-mechanical polishing compositions that are effective for removal of amorphous silicon typically exhibit low tetraethylorthosilicate (TEOS) removal rates. Similarly, chemical-mechanical polishing compositions that are effective for removal of polysilicon typically exhibit low TEOS removal rates.

Thus, a need remains for compositions and methods for chemical-mechanical polishing to effectively remove TEOS, while maintaining suitable polishing rates for other materials such as, for example, polysilicon and amorphous silicon. The invention provides such polishing compositions and methods. These and other advantages of the invention, as well as additional inventive features, will be apparent from the description of the invention provided herein.

### BRIEF SUMMARY OF THE INVENTION

The invention provides a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) a cationic polymer, (c) a buffering agent, and (d) water, wherein the polishing composition has a pH of about 1 to about 6.

The invention further provides a method of chemically-mechanically polishing a substrate comprising: (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) a cationic polymer, (c) a buffering agent, and (d) water, wherein the polishing composition has a pH of about 1 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

### DETAILED DESCRIPTION OF THE INVENTION

The invention provides a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) a cationic polymer, (c) a buffering agent, and (d) water, wherein the polishing composition has a pH of about 1 to about 6.

The chemical-mechanical polishing composition comprises colloidal silica particles, wherein the colloidal silica particles are surface-modified with an aminosilane compound. As used herein, the terms “colloidal silica abrasive,” “colloidal silica abrasive particle,” and “colloidal silica particle” can be used interchangeably, and can refer to any silica particle that is colloidally stable in the polishing composition. The term colloid refers to the suspension of particles in the liquid carrier (e.g., water). Colloidal stability refers to the maintenance of that suspension through time. In the context of this invention, an abrasive is considered colloidally stable if, when the abrasive is placed into a 100 mL graduated cylinder and allowed to stand unagitated for a time of 2 hours, the difference between the concentration of particles in the bottom 50 mL of the graduated cylinder ([B] in terms of g/mL) and the concentration of particles in the top 50 mL of the graduated cylinder ([T] in terms of g/mL) divided by the initial concentration of particles in the abrasive composition ([C] in terms of g/mL) is less than or equal to 0.5 (i.e., {[B]−[T]}/[C]≤0.5). More preferably, the value of {[B]−[T]}/[C] is less than or equal to 0.3, and most preferably is less than or equal to 0.1.

In some embodiments, the colloidal silica particles are prepared via a wet process rather than a pyrogenic or flame hydrolysis process which produces structurally different particles. A suitable dispersion may include both aggregated and non-aggregated colloidal silica particles. As is known to those of ordinary skill in the art, non-aggregated particles are individually discrete particles that may be spherical or nearly spherical in shape but can have other shapes as well. These non-aggregated particles are referred to as primary particles. Aggregated particles are particles in which multiple discrete particles (primary particles) have clustered or bonded together to form aggregates having generally irregular shapes. Aggregated particles may include two, three, or more connected primary particles. The colloidal silica may be precipitated or condensation-polymerized silica, which may be prepared using any method known to those of ordinary skill in the art, such as by the sol gel method or by silicate ion-exchange. Condensation-polymerized silica particles are often prepared by condensing Si(OH)₄ to form substantially spherical particles.

The colloidal silica particles are surface-modified with an aminosilane compound. As used herein, the term “surface-modified” means that an aminosilane compound is bonded to or chemically attached to the surface of the colloidal silica particle, for example, via a condensation reaction between the silane group(s) in the modifying aminosilane compound and surface silanol group(s) on the colloidal silica particle.

In some embodiments, the surface modification level of the aminosilane compound on the surface of the colloidal silica is at least about 5 percent (i.e., at least about 5 percent of the silanol groups on the colloidal silica particles are reacted with the aminosilane compound). For example, the surface-modified colloidal silica particles can have a modification level of at least about 5%, at least about 6%, at least about 7%, at least about 8%, at least about 9%, or at least about 10% to achieve the desired polishing results. Alternatively, or additionally, the surface-modified colloidal silica particles can have a modification level of about 50% or less, about 45% or less, about 40% or less, about 35% or less, about 30% or less, about 25% or less, or about 20% or less to promote colloidal stability of the colloidal silica particles in the polishing composition. Accordingly, the colloidal silica particles may have a percent theoretical surface coverage that is bounded by any two of the aforementioned endpoints.

For example, the colloidal silica particles can have an average surface modification level of the aminosilane compound of from about 5% to about 50%, from about 5% to about 45%, from about 5% to about 40%, from about 5% to about 35%, from about 5% to about 30%, from about 5% to about 25%, from about 5% to about 20%, from about 6% to about 50%, from about 6% to about 45%, from about 6% to about 40%, from about 6% to about 35%, from about 6% to about 30%, from about 6% to about 25%, from about 6% to about 20%, from about 7% to about 50%, from about 7% to about 45%, from about 7% to about 40%, from about 7% to about 35%, from about 7% to about 30%, from about 7% to about 25%, from about 7% to about 20%, from about 8% to about 50%, from about 8% to about 45%, from about 8% to about 40%, from about 8% to about 35%, from about 8% to about 30%, from about 8% to about 25%, from about 8% to about 20%, from about 9% to about 50%, from about 9% to about 45%, from about 9% to about 40%, from about 9% to about 35%, from about 9% to about 30%, from about 9% to about 25%, from about 9% to about 20%, from about 10% to about 50%, from about 10% to about 45%, from about 10% to about 40%, from about 10% to about 35%, from about 10% to about 30%, from about 10% to about 25%, or from about 10% to about 20%. In some embodiments, the colloidal silica particles have an average surface modification level of the aminosilane compound of from about 5% to about 50%. In certain embodiments, the colloidal silica particles have an average surface modification level of the aminosilane compound of from about 10% to about 50%.

It will be appreciated that the condensation reaction between the silane group(s) in the modifying aminosilane compound and surface silanol group(s) on the colloidal silica particle may be a reversible equilibrium reaction, such that the actual modification level may not equal the theoretical modification level (a modification level calculated based on the amount of aminosilane added to the composition). Moreover, the actual modification level in the polishing composition may depend upon the procedures used to formulate the composition. It will be appreciated that some procedures may strip or otherwise remove the aminosilane compound from the surface of the colloidal silica, thereby reducing the modification level.

The modification level of the colloidal silica can be measured using the following procedure. The polishing composition is first passed through a mixed bed ion exchange column to remove unbound or loosely bound aminosilane from the colloidal silica particles. After ionic exchange, the total aminosilane concentration in the polishing composition (both bound and unbound) is determined by digesting the composition (including the modified colloidal silica particles) in concentrated potassium hydroxide and evaluating the digested composition using proton nuclear magnetic resonance (NMR). The amount of unbound (e.g., dissolved) aminosilane in the polishing composition is determined by first removing the modified colloidal silica particles from the composition by ultra-centrifugation (e.g., at 40,000 rpm for 1 hour) and then testing the decanted liquid layer using liquid chromatography mass spectrometry (LCMS) (for aminosilane concentrations in a range from about 1 to about 100 ppm) and/or NMR (for aminosilane concentrations in a range from about 100 to about 5000 ppm). The amount of bound (modifying) aminosilane is calculated as the difference between the measured total aminosilane and the measured unbound aminosilane. The modification level may then be calculated based upon the concentration of colloidal silica particles in the polishing composition and the BET surface area thereof (measured as described in Colloids and Surfaces A: Physicochem. Eng. Aspects 322 (2008) 248-252). For the purposes of this calculation the average number of surface silanol groups on the colloidal silica is assumed to be 4.5 per nm².

The surface-modified colloidal silica particles can be prepared by any suitable method. For example, the surface-modified colloidal silica particles can be prepared by admixing a sufficient amount of the aminosilane compound with a predetermined volume (or mass) of colloidal silica dispersion. The admixture may be heated, for example, to a temperature of at least 50° C. (e.g., at least 60° C., at least 65° C., or at least 70° C.) to promote a condensation reaction between the silane group(s) in the modifying aminosilane compound and surface silanol group(s) on the colloidal silica particle. The admixture may be heated for substantially any suitable time duration, for example, at least one hour (e.g., at least two hours, at least five hours, or at least ten hours). After cooling to room temperature, the resulting dispersion (including the modified colloidal silica particles) may optionally be passed through an ion exchange column to remove any unreacted aminosilane compound (or other impurities).

In some embodiments, the polishing composition including the surface-modified colloidal silica particles has less than about 50 ppm (e.g., less than about 40 ppm, less than about 30 ppm, less than about 20 ppm, or less than about 10 ppm) of the modifying aminosilane compound free in the liquid carrier per 1 wt. % of the surface-modified colloidal silica particles. By “free,” it is meant that modifying aminosilane compound is not bound to the particle (e.g., dissolved in the liquid carrier or agglomerated and suspended in the liquid carrier). Thus, for example, a polishing composition including 0.3 weight percent of the surface-modified colloidal silica particles preferably has less than about 15 ppm (e.g., less than about 12 ppm, less than about 9 ppm, less than about 6 ppm, or less than about 3 ppm) of the modifying aminosilane compound free in the liquid carrier. Likewise, a polishing composition including 3 weight percent of the surface-modified colloidal silica particles (e.g., a concentrate) preferably has less than about 150 ppm (e.g., less than about 120 ppm, less than about 90 ppm, less than about 60 ppm, or less than about 30 ppm) of the modifying aminosilane compound free in the liquid carrier.

The surface-modified colloidal silica particles may include any suitable colloidal silica particles. For example, the surface-modified colloidal silica particles may have any suitable average particle size as measured using a CPS Disc Centrifuge Particle size analyzer (e.g., Model DC24000 HR available from CPS Instruments, Prairieville, Louisiana). Note that as used herein the average particle size is taken to be the D50 of the measured distribution. For example, the surface-modified colloidal silica particles can have an average particle size in a range from about 5 nm to about 300 nm (e.g., from about 10 nm to about 200 nm, from about 20 nm to about 200 nm, or from about 30 nm to about 150 nm). However, it has been found that in certain preferred embodiments, the surface-modified colloidal silica particles may have an average particle size in a range from about 30 nm to about 100 nm (e.g., from about 30 nm to about 80 nm, from about 30 nm to about 60 nm, or from about 45 nm to about 55 nm). Thus, in some embodiments, the colloidal silica particles (i.e., the surface-modified colloidal silica particles) have a D50 particle size in a range from about 30 nm to about 80 nm. In some embodiments, the colloidal silica particles (i.e., the surface-modified colloidal silica particles) have a D50 particle size in a range from about 30 nm to about 60 nm. In certain embodiments, the colloidal silica particles (i.e., the surface-modified colloidal silica particles) have a D50 particle size in a range from about 45 nm to about 55 nm.

The surface-modified colloidal silica particles can have any suitable surface area. For example, the surface-modified colloidal silica particles may further be characterized as having a BET surface area in a range from about 20 m²/g to about 200 m²/g (e.g., in a range from about 30 m²/g to about 180 m²/g, from about 40 m²/g to about 160 m²/g, from about 50 m²/g to about 150 m²/g, or from about 60 m²/g to about 120 m²/g). The BET surface area may be measured, for example, as described in Colloids and Surfaces A: Physicochem. Eng. Aspects 322 (2008) 248-252. In some embodiments, the colloidal silica particles (i.e., the surface-modified colloidal silica particles) have a Brunauer-Emmett-Teller (BET) surface area from about 60 m²/g to about 120 m²/g.

The surface-modified colloidal silica particles can have any suitable aspect ratio, however, in certain advantageous embodiments it has been found that surface-modified colloidal silica particles having a higher aspect ratio may achieve improved patterned wafer polishing performance. Accordingly, the surface-modified colloidal silica particles may be further characterized as having a number average aspect ratio of greater than about 1.1 (e.g., greater than about 1.15, greater than about 1.2, greater than about 1.25, greater than about 1.3, greater than about 1.35, or greater than about 1.4). In some embodiments, the colloidal silica particles (i.e., the surface-modified colloidal silica particles) have an aspect ratio of greater than about 1.2.

The aspect ratio of a colloidal silica particle is defined herein as the maximum caliper diameter of the particle divided by the minimum caliper diameter of the particle (hence the aspect ratio is always greater than or equal to 1). The number average aspect ratio represents a statistical measure of the average (median) aspect ratio of the colloidal silica particles in the polishing composition (on a number rather than a weight basis). The number average aspect ratio may be referred to as AR50 since statistically half (50%) of the particles have an aspect ratio less than the median value and half (50%) of the particles have an aspect ratio greater than the median value.

The number average aspect ratio of the colloidal silica particles in a polishing composition may be determined by evaluating a large number of particles in high magnification transmission electron microscopy (TEM) images (e.g., at a magnification in a range from about 10,000 to about 30,000). To obtain a statistically significant median aspect ratio it is generally necessary to measure and compute the aspect ratio for a large number of colloidal silica particles (e.g., at least 500 or more particles or even 1000 or more particles) using a plurality of images (e.g., at least 10 or more images, 15 or more images, or even 20 or more images). The maximum caliper diameter and the minimum caliper diameter of each of the particles may be measured manually (particle by particle), for example, using the scale bar on the TEM image. However, a user-guided automated process is practically preferred based upon the requirement to evaluate a large number of particles. Such automated processes preferably make use of commercially available image analysis software.

The surface-modified colloidal silica particles can have any suitable degree of aggregation. In other words, the surface-modified colloidal silica particles may be aggregated, partially aggregated, and/or non-aggregated. For example, in some embodiments, a portion of the particles may be aggregated, and the remainder may be non-aggregated. Non-aggregated particles are individually discrete particles (commonly referred to in the art as primary particles or primaries) that are generally spherical or nearly spherical in shape. Aggregated particles are particles in which multiple primary particles are clustered or bonded together to form aggregates having generally irregular or non-spherical shapes (such as elongated or branched). Non-aggregated (primary) particles may also be referred to herein as monomers. Aggregated particles may also be referred to as dimers (having two primaries), trimers (having three primaries), tetramers (having four primaries), and so on.

In some embodiments, the surface-modified colloidal silica particles are substantially non-aggregated. As used herein, “substantially non-aggregated” refers to a composition where less than 50 percent of the surface-modified colloidal silica particles are aggregated. In other words, a “substantially non-aggregated” composition includes mostly primary particles, i.e., 50 percent or more primary particles. In other embodiments, the surface-modified colloidal silica particles may be partially aggregated. As used herein, the term “partially aggregated” refers to a composition where 50 percent or more of the surface-modified colloidal silica particles include two or more aggregated primary particles or that 30 percent or more (or 45 percent or more) of the colloidal silica particles include three or more aggregated primary particles. In still other embodiments, the surface-modified colloidal silica particles may have an aggregate distribution in which 20 percent or more of the surface-modified colloidal silica particles include less than three primary particles (i.e., non-aggregated primary particles or aggregated particles having just two primary particles, also referred to as monomers and dimers) and 50 percent or more of the surface-modified colloidal silica particles include three or more aggregated primary particles.

Partially aggregated colloidal silica abrasives may be prepared, for example, using a multi-step process in which primary particles are first grown in solution, for example, as described in U.S. Pat. No. 5,230,833. The pH of the solution may then be adjusted to an acidic value for a predetermined time period to promote aggregation (or partial aggregation), for example, as described in U.S. Pat. No. 8,529,787. An optional final step may allow for further growth of the aggregates (and any remaining primary particles).

The surface-modified colloidal silica particles have a positive charge in the polishing composition (e.g., in the liquid carrier). The charge on colloidal silica particles is commonly referred to in the art as the zeta potential (or the electrokinetic potential). As known to those of ordinary skill in the art, the zeta potential of a particle refers to the electrical potential difference between the electrical charge of the ions surrounding the particle and the electrical charge of the bulk solution of the polishing composition (e.g., the liquid carrier and any other components dissolved therein). The zeta potential of a dispersion such as a polishing composition may be obtained using the Model DT-1202 Acoustic and Electro-acoustic spectrometer available from Dispersion Technologies, Inc. (Bedford Hills, N.Y.) or with electrophoretic light scattering using a Malvern Zetasizer available from Malvern Panalytical (Malvern, United Kingdom).

In some embodiments, the surface-modified colloidal silica particles have a zeta potential of greater than 0 mV when measured in the polishing composition. For example, the colloidal silica particles (i.e., the surface-modified colloidal silica particles) can have a zeta potential of at least about 10 mV in the chemical-mechanical polishing composition, a zeta potential of at least about 11 mV in the chemical-mechanical polishing composition, a zeta potential of at least about 12 mV in the chemical-mechanical polishing composition, a zeta potential of at least about 13 mV in the chemical-mechanical polishing composition, a zeta potential of at least about 14 mV in the chemical-mechanical polishing composition, a zeta potential of at least about 15 mV in the chemical-mechanical polishing composition, a zeta potential of at least about 20 mV in the chemical-mechanical polishing composition, a zeta potential of at least about 25 mV in the chemical-mechanical polishing composition, or a zeta potential of at least about 30 mV in the chemical-mechanical polishing composition.

In some embodiments, the colloidal silica abrasive particles (i.e., the surface-modified colloidal silica particles) have a positive zeta potential of from about 0 mV to about 60 mV, e.g., from about 10 mV to about 60 mV, from about 10 mV to about 50 mV, from about 11 mV to about 50 mV, from about 12 mV to about 50 mV, from about 13 mV to about 50 mV, from about 14 mV to about 50 mV, from about 15 mV to about 60 mV, from about 15 mV to about 50 mV, from about 15 mV to about 40 mV, from about 15 mV to about 35 mV, from about 15 mV to about 30 mV, from about 15 mV to about 25 mV, from about 20 mV to about 60 mV, from about 20 mV to about 50 mV, from about 20 mV to about 40 mV, from about 20 mV to about 35 mV, from about 20 mV to about 30 mV, from about 30 mV to about 60 mV, from about 30 mV to about 50 mV, from about 30 mV to about 40 mV, from about 30 mV to about 35 mV. In some embodiments, the colloidal silica particles (i.e., the surface-modified colloidal silica particles) have a zeta potential in the polishing composition of about 20 mV to about 50 mV. In certain embodiments, the colloidal silica particles (i.e., the surface-modified colloidal silica particles) have a zeta potential in the polishing composition of about 30 mV to about 40 mV.

It will be appreciated that the surface modification with an aminosilane compound may increase the isoelectric point (IEP) of the particles (as compared to colloidal silica particles that are not surface-modified or have a lower modification level). In some embodiments of the present invention, the IEP of the surface-modified colloidal silica particles is at least about 6 (e.g., at least about 6.2, at least about 6.5, or at least about 7). For example, the surface-modified colloidal silica particles can have an IEP of about 6 to about 10, about 6.2 to about 10, about 6.5 to about 10, about 7 to about 10, about 7.5 to about 10, about 8 to about 10, about 6 to about 9.5, about 6.2 to about 9.5, about 6.5 to about 9.5, about 7 to about 9.5, about 7.5 to about 9.5, about 8 to about 9.5, about 6 to about 9, about 6.2 to about 9, about 6.5 to about 9, about 7 to about 9, about 7.5 to about 9, about 8 to about 9, about 6 to about 8.5, about 6.2 to about 8.5, about 6.5 to about 8.5, about 7 to about 8.5, or about 7.5 to about 8.5. In some embodiments, the colloidal silica particles (i.e., the surface-modified colloidal silica particles) have an isoelectric point of about 6.2 to about 10. In some embodiments, the colloidal silica particles (i.e., the surface-modified colloidal silica particles) have an isoelectric point of about 6.5 to about 9. In certain embodiments, the colloidal silica particles (i.e., the surface-modified colloidal silica particles) have an isoelectric point of about 7 to about 9.

For the purposes of this disclosure, the IEP is measured on the as-modified colloidal silica particles before the addition of other polishing composition compounds (e.g., the buffering agent and the biocide). The IEP is determined by titrating a sample using the electroacoustic method (e.g., via a Colloidal Dynamics Zetaprobe). The colloidal silica dispersion is diluted in deionized water to a solids (silica) concentration in a range from 2 to 5 weight percent. The diluted sample is titrated with 0.1N potassium hydroxide for a base titration (sample pH to 10.5). The zeta potential is measured at least every 0.5 pH units during the titration. The IEP is identified by determining the pH value at which the zeta potential is 0 mV. The precise IEP value may be computed via interpolation between the pH values at which the zeta potential transitions from positive to negative.

The modifying aminosilane compound can be any suitable aminosilane compound, for example, including primary aminosilanes, secondary aminosilanes, tertiary aminosilanes, quaternary aminosilanes, monopodal aminosilanes, multipodal (e.g., dipodal) aminosilanes, or a combination thereof. In some embodiments, the aminosilane compound is a monopodal aminosilane compound. As used herein, the term “monopodal aminosilane compound” refers to an aminosilane compound that is bonded to or chemically attached to the surface of the colloidal silica particle in a monodentate manner. In other embodiments, the aminosilane compound is a multipodal aminosilane compound. As used herein, the term “multipodal aminosilane compound” refers to a compound that is bonded to or chemically attached to the surface of the colloidal silica particle with more than one bond or coordination (e.g., bidentate, tridentate, or the like).

For example, the aminosilane compound can be any suitable aminosilane compound selected from bis(2-hydroxyethyl)-3-aminopropyl trialkoxysilane (e.g., bis(2-hydroxyethyl)-3-aminopropyl trimethoxysilane), diethylaminomethyltrialkoxysilane (e.g., diethylaminomethyltrimethoxysilane), (N,N-diethyl-3-aminopropyl)trialkoxysilane (e.g., (N,N-diethyl-3-aminopropyl)trimethoxysilane), 3-(N-styrylmethyl-2-aminoethylamino)propyltrialkoxysilane (e.g., 3-(N-styrylmethyl-2-aminoethylamino)propyltrimethoxysilane), aminopropyl trialkoxysilane (e.g., aminopropyl trimethoxysilane), N-(2-N-benzylaminoethyl)-3-aminopropyltrialkoxysilane (e.g., N-(2-N-benzylaminoethyl)-3-aminopropyltrimethoxysilane), trialkoxysilyl propyl-N,N,N-trimethyl ammonium (e.g., trimethoxysilyl propyl-N,N,N-trimethyl ammonium), N-(trialkoxysilylethyl)benzyl-N,N,N-trimethyl ammonium (e.g., N-(trimethoxysilylethyl)benzyl-N,N,N-trimethyl ammonium), (bis(methyldialkoxysilylpropyl)-N-methyl amine, bis(trialkoxysilylpropyl) urea, bis(3-(trialkoxysilyl)propyl)-ethylenediamine, bis(trialkoxysilylpropyl)amine, 3-aminopropyltrialkoxysilane, N-(2-aminoethyl)-3-aminopropylmethyldialkoxysilane, N-(2-aminoethyl)-3-aminopropyltrialkoxysilane, 3-aminopropylmethyldialkoxysilane, 3-aminopropyltrialkoxysilane, (N-trialkoxysilylpropyl) polyethyleneimine, trialkoxysilylpropyldiethylenetriamine, N-phenyl-3-aminopropyltrialkoxysilane, N-(vinylbenzyl)-2-aminoethyl-3-aminopropyltrialkoxysilane, 4-aminobutyltrialkoxysilane, salts thereof, and mixtures thereof. In any of the foregoing exemplary aminosilane compounds, the alkyl or alkoxy substituent can be any linear or branched C₁₋₆ alkyl or alkoxy group. In certain embodiments, the aminosilane compound is a propyl group containing aminosilane or an aminosilane compound including a propyl amine.

In certain embodiments, the aminosilane compound is a multipodal (e.g., dipodal) aminosilane, such as, for example, bis(trialkoxysilyl) ethane, bis(trialkoxysilylalkyl)amine (e.g., bis(trialkoxysilylalkyl)amine or bis(trialkoxysilylpropyl)amine), N-(hydroxyalkyl)-N,N-bis(trialkoxysilylalkyl)amine, N,N′-bis[(3-trialkoxysilyl)alkyl]ethylenediamine, N,N′-bis(2-hydroxyalkyl)-N,N′-bis(trialkoxysilylalkyl)ethylenediamine, tris(trialkoxysilylalkyl)amine, 1,11-bis(trialkoxysilyl)-4-oxa-8-azaundecan-6-ol, salts thereof, or mixtures thereof. In any of the foregoing exemplary aminosilane compounds, the alkyl or alkoxy substituent can be any linear or branched C₁-6 alkyl or alkoxy group. In certain embodiments, the aminosilane compound is a propyl group containing aminosilane or an aminosilane compound including a propyl amine.

The colloidal silica particles (i.e., the surface-modified colloidal silica particles) can be present in the polishing composition in any suitable amount. If the polishing composition of the invention comprises too little abrasive, the composition may not exhibit sufficient removal rate. In contrast, if the polishing composition comprises too much abrasive, then the polishing composition may exhibit undesirable polishing performance and/or may not be cost effective and/or may lack stability. The polishing composition can comprise about 10 wt. % or less of the colloidal silica particles (i.e., the surface-modified colloidal silica particles), for example, about 9 wt. % or less, about 8 wt. % or less, about 7 wt. % or less, about 6 wt. % or less, about 5 wt. % or less, about 4 wt. % or less, about 3 wt. % or less, about 2 wt. % or less, about 1 wt. % or less, about 0.9 wt. % or less, about 0.8 wt. % or less, about 0.7 wt. % or less, about 0.6 wt. % or less, or about 0.5 wt. % or less of the colloidal silica particles (i.e., the surface-modified colloidal silica particles). Alternatively, or in addition, the polishing composition can comprise about 0.001 wt. % or more of the colloidal silica particles (i.e., the surface-modified colloidal silica particles), for example, about 0.005 wt. % or more, about 0.01 wt. % or more, 0.05 wt. % or more, about 0.1 wt. % or more, about 0.2 wt. % or more, about 0.3 wt. % or more, about 0.4 wt. % or more, about 0.5 wt. % or more, or about 1 wt. % or more of the colloidal silica particles (i.e., the surface-modified colloidal silica particles). Thus, the polishing composition can comprise colloidal silica particles (i.e., the surface-modified colloidal silica particles) in an amount bounded by any two of the aforementioned endpoints, as appropriate.

For example, in some embodiments, the colloidal silica particles (i.e., the surface-modified colloidal silica particles) can be present in the polishing composition in an amount of from about 0.001 wt. % to about 10 wt. % of the polishing composition, e.g., about 0.001 wt. % to about 8 wt. %, about 0.001 wt. % to about 6 wt. %, about 0.001 wt. % to about 5 wt. %, about 0.001 wt. % to about 4 wt. %, about 0.001 wt. % to about 2 wt. %, about 0.001 wt. % to about 1 wt. %, about 0.01 wt. % to about 10 wt. %, about 0.01 wt. % to about 8 wt. %, about 0.01 wt. % to about 6 wt. %, about 0.01 wt. % to about 5 wt. %, about 0.01 wt. % to about 4 wt. %, about 0.01 wt. % to about 2 wt. %, about 0.01 wt. % to about 1 wt. %, about 0.05 wt. % to about 10 wt. %, about 0.05 wt. % to about 8 wt. %, about 0.05 wt. % to about 6 wt. %, about 0.05 wt. % to about 5 wt. %, about 0.05 wt. % to about 4 wt. %, about 0.05 wt. % to about 2 wt. %, about 0.05 wt. % to about 1 wt. %, about 0.1 wt. % to about 10 wt. %, about 0.1 wt. % to about 8 wt. %, about 0.1 wt. % to about 6 wt. %, about 0.1 wt. % to about 5 wt. %, about 0.1 wt. % to about 4 wt. %, about 0.1 wt. % to about 2 wt. %, about 0.1 wt. % to about 1 wt. %, about 0.5 wt. % to about 10 wt. %, about 0.5 wt. % to about 8 wt. %, about 0.5 wt. % to about 5 wt. %, about 0.5 wt. % to about 4 wt. %, about 0.5 wt. % to about 2 wt. %, about 0.5 wt. % to about 1 wt. %, about 1 wt. % to about 10 wt. %, about 1 wt. % to about 8 wt. %, about 1 wt. % to about 6 wt. %, about 1 wt. % to about 5 wt. %, about 1 wt. % to about 4 wt. %, or about 1 wt. % to about 2 wt. %. In some embodiments, the polishing composition comprises about 0.001 wt. % to about 10 wt. % of the colloidal silica particles (i.e., the surface-modified colloidal silica particles). In certain embodiments, the polishing composition comprises about 0.1 wt. % to about 1 wt. % of the colloidal silica particles (i.e., the surface-modified colloidal silica particles).

The chemical-mechanical polishing composition comprises a cationic polymer. The cationic polymer can comprise any suitable cationic monomer capable of undergoing free radical polymerization and/or addition polymerization. In some embodiments, the cationic polymer comprises a cationic monomer selected from N-vinylimidazole, 2-(dimethylamino)ethyl acrylate (“DMAEA”), 2-(dimethylamino)ethyl methacrylate (“DMAEM”), 3-(dimethylamino)propyl methacrylamide (“DMAPMA”), 3-(dimethylamino)propyl acrylamide (“DMAPA”), 3-methacrylamidopropyl-trimethyl-ammonium chloride (“MAPTAC”), 3-acrylamidopropyl-trimethyl-ammonium chloride (“APTAC”), diallyldimethylammonium chloride (“DADMAC”), 2-(acryloyloxy)-N,N,N-trimethylethanaminium chloride (“DMAEA.MCQ”), 2-(methacryloyloxy)-N,N,N-trimethylethanaminium chloride (“DMAEM.MCQ”), N,N-dimethylaminoethyl acrylate benzyl chloride (“DMAEA.BCQ”), N,N-dimethylaminoethyl methacrylate benzyl chloride (“DMAEM.BCQ”), ethylenimine, salts thereof, and combinations thereof. It will be understood from the foregoing list, that any alternative anion counterion (e.g., bromide, iodide, sulfate, methanesulfonate, and phosphate) is also suitable. Alternatively, the cationic polymer can comprise a cationic amino acid monomer. For example, in some embodiments, the cationic polymer comprises arginine, histidine, or lysine. In certain embodiments, the cationic polymer is polylysine. It will be understood that polylysine may include ε-polylysine and/or α-polylysine composed of D-lysine and/or L-lysine. The polylysine may thus include α-poly-L-lysine, α-poly-D-lysine, ε-poly-L-lysine, ε-poly-D-lysine, salts thereof, and mixtures thereof.

Exemplary cationic polymers include, but are not limited to, polyethylenimine (PEI), poly(vinylimidazolium), poly(methacryloyloxyethyltrimethylammonium) chloride (polyMADQUAT), poly(diallyldimethylammonium) chloride (polyDADMAC) (e.g., Polyquaternium-6), poly(dimethylamine-co-epichlorohydrin), poly[bis(2-chloroethyl) ether-alt-1,3-bis[3-(dimethylamino)propyl]urea] (e.g., Polyquaternium-2), copolymers of hydroxyethyl cellulose and diallyldimethylammonium (e.g., Polyquaternium-4), copolymers of acrylamide and diallyldimethylammonium (e.g., Polyquaternium-7), quaternized hydroxyethylcellulose ethoxylate (e.g., Polyquaternium-10), copolymers of vinylpyrrolidone and quaternized dimethylaminoethyl methacrylate (e.g., Polyquatemium-11), copolymers of vinylpyrrolidone and quaternized vinylimidazole (e.g., Polyquatemium-16), a terpolymer of vinylcaprolactam, vinylpyrrolidone, and quaternized vinylimidazole (e.g., Polyquaternium-46), 3-methyl-1-vinylimidazolium methyl sulfate-N-vinylpyrrolidone copolymer (e.g., Polyquaternium-44), copolymers of vinylpyrrolidone and diallyldimethylammonium, Luviquat® Supreme, Luviquat® Hold, Luviquat® UltraCare, Luviquat® FC 370, Luviquat® FC 550, Luviquat® FC 552, Luviquat® Excellence, GOHSEFIMER K210™, GOHSENX K-434, salts thereof, and combinations thereof. In some embodiments, the cationic polymer is or comprises poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly [bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof. In certain embodiments, the cationic polymer is or comprises poly(diallyldimethylammonium) chloride (polyDADMAC) or a salt thereof.

The polishing composition can comprise any suitable amount of the cationic polymer. The polishing composition can comprise about 10 ppm or more of the cationic polymer, for example, about 15 ppm or more, about 20 ppm or more, about 25 ppm or more, about 30 ppm or more, about 35 ppm or more, or about 40 ppm or more. Alternatively, or in addition, the polishing composition can comprise about 1000 ppm or less of the cationic polymer, for example, about 800 ppm or less, about 600 ppm or less, about 400 ppm or less, about 200 ppm or less, or about 100 ppm or less. Thus, the polishing composition can comprise the cationic polymer in an amount bounded by any two of the aforementioned endpoints. For example, the polishing composition can comprise about 10 ppm to about 1000 ppm of the cationic polymer, e.g., about 10 ppm to about 800 ppm, about 10 ppm to about 600 ppm, about 10 ppm to about 400 ppm, about 10 ppm to about 200 ppm, about 10 ppm to about 100 ppm, about 25 ppm to about 1000 ppm, about 25 ppm to about 800 ppm, about 25 ppm to about 600 ppm, about 25 ppm to about 400 ppm, about 25 ppm to about 200 ppm, or about 25 ppm to about 100 ppm. In some embodiments, the polishing composition comprises about 100 ppm to about 1000 ppm of the cationic polymer. In certain embodiments, the polishing composition comprises about 200 ppm to about 500 ppm of the cationic polymer.

The cationic polymer can exist as any suitable structure type. For example, the cationic polymer can exist as an alternating polymer, a random polymer, a block polymer, a graft polymer, a linear polymer, a branched polymer, or a combination thereof. The cationic polymer can contain a single monomer unit, or any suitable number of different monomer units. For example, the cationic polymer can contain 2 different monomer units, 3 different monomer units, 4 different monomer units, 5 different monomer units, or 6 different monomer units. The cationic monomers of the cationic polymer can exist in any suitable concentration and any suitable proportion.

The cationic polymer can have any suitable weight average molecular weight. The cationic polymer can have a weight average molecular weight of about 150 g/mol or more, for example, about 300 g/mol or more, about 500 g/mol or more, about 600 g/mol or more, about 750 g/mol or more, about 1000 g/mol or more, about 1500 g/mol or more, about 2000 g/mol or more, about 2500 g/mol or more, about 3000 g/mol or more, about 3500 g/mol or more, about 4000 g/mol or more, about 4500 g/mol or more, about 5000 g/mol or more, about 5500 g/mol or more, about 6000 g/mol or more, about 6500 g/mol or more, about 7000 g/mol or more, or about 7500 g/mol or more. Alternatively, or in addition, the cationic polymer can have a weight average molecular weight of about 10000 g/mol or less, for example, about 9000 g/mol or less, about 8000 g/mol or less, about 7500 g/mol or less, about 7000 g/mol or less, about 6500 g/mol or less, about 6000 g/mol or less, about 5500 g/mol or less, about 5000 g/mol or less, about 4500 g/mol or less, about 4000 g/mol or less, about 3500 g/mol or less, about 3000 g/mol or less, about 2500 g/mol or less, or about 2000 g/mol or less. Thus, cationic polymer can have a weight average molecular weight bounded by any two of the aforementioned endpoints. For example, the cationic polymer can have a weight average molecular weight of about 150 g/mol to about 10000 g/mol, e.g., about 300 g/mol to about 9000 g/mol, about 500 g/mol to about 8000 g/mol, about 150 g/mol to about 7000 g/mol, about 150 g/mol to about 6000 g/mol, about 150 g/mol to about 5000 g/mol, about 150 g/mol to about 2000 g/mol, about 1000 g/mol to about 10000 g/mol, about 1000 g/mol to about 9000 g/mol, about 1000 g/mol to about 8000 g/mol, about 1000 g/mol to about 7000 g/mol, about 1000 g/mol to about 6000 g/mol, or about 1000 g/mol to about 5000 g/mol.

The chemical-mechanical polishing composition comprises a buffering agent. The buffering agent preferably possesses an acceptable buffering capacity at the desired pH of the polishing composition. The buffering agent typically includes one or more acids and one or more salts of the acid in relative amounts sufficient to establish the pH of the chemical-mechanical polishing composition at a desired pH value (i.e., a pH of about 1 to about 6), and to maintain that pH within an acceptable range above and below the desired pH during the chemical-mechanical polishing process. For example, the buffering agent can comprise an organic acid (e.g., a carboxylic acid, a phosphonic acid, or the like) or an inorganic acid (e.g., a phosphoric acid or the like) capable of providing a suitable buffering capacity at a desired acidic pH value. In some embodiments, the organic acid comprises a carboxylic acid, a phosphonic acid, or a combination thereof. Non-limiting examples of suitable carboxylic acids include monocarboxylic acids (e.g., acetic acid, benzoic acid, phenylacetic acid, 1-naphthoic acid, 2-naphthoic acid, glycolic acid, formic acid, lactic acid, mandelic acid, and the like) and polycarboxylic acids (e.g., oxalic acid, malonic acid, succinic acid, adipic acid, tartaric acid, citric acid, maleic acid, fumaric acid, aspartic acid, glutamic acid, phthalic acid, isophthalic acid, terephthalic acid, 1,2,3,4-butanetetracarboxylic acid, itaconic acid, and the like), as well as amino acids (e.g., glycine, proline, asparagine, glutamine, glutamic acid, aspartic acid, phenylalanine, alanine, beta-alanine, and the like). Non-limiting examples of suitable organic phosphonic acids include, DEQUEST™ 2060 (i.e., diethylene triamine penta(methylene-phosphonic acid)), DEQUEST™ 7000 (i.e., 2-phosphonobutane-1,2,4-tricarboxylic acid), and DEQUEST™ 2010 (i.e., hydroxyethylidene-1,1-diphosphonic acid), all of which are available from Solutia, Inc., as well as phosphonoacetic acid, iminodi (methylphosphonic acid), and the like. In some embodiments, the buffering agent comprises an organic acid. In certain embodiments, the buffering agent comprises formic acid, malonic acid, acetic acid, oxalic acid, citric acid, or a combination thereof. In preferred embodiments, the buffering agent comprises acetic acid.

The buffering agent can be present in the polishing composition in any suitable amount. The polishing composition can comprise about 5 wt. % or less of the buffering agent, for example, about 4 wt. % or less, about 3 wt. % or less, about 2 wt. % or less, about 1.5 wt. % or less, about 1 wt. % or less, or about 0.5 wt. % or less of the buffering agent. Alternatively, or in addition, the polishing composition can comprise about 0.001 wt. % or more of the buffering agent, for example, about 0.005 wt. % or more, about 0.01 wt. % or more, about 0.05 wt. % or more, about 0.1 wt. % or more, or 0.5 wt. % or more of the buffering agent. Thus, the polishing composition can comprise the buffering agent in an amount bounded by any two of the aforementioned endpoints, as appropriate.

For example, in some embodiments, the buffering agent can be present in the polishing composition in an amount of from about 0.001 wt. % to about 5 wt. % of the polishing composition, e.g., about 0.001 wt. % to about 4 wt. %, about 0.001 wt. % to about 3 wt. %, about 0.001 wt. % to about 2 wt. %, about 0.001 wt. % to about 1.5 wt. %, about 0.001 wt. % to about 1 wt. %, about 0.001 wt. % to about 0.5 wt. %, 0.05 wt. % to about 5 wt. %, about 0.05 wt. % to about 4 wt. %, about 0.05 wt. % to about 3 wt. %, about 0.05 wt. % to about 2 wt. %, about 0.05 wt. % to about 1.5 wt. %, about 0.05 wt. % to about 1 wt. %, about 0.05 wt. % to about 0.5 wt. %, 0.05 wt. % to about 5 wt. %, about 0.05 wt. % to about 4 wt. %, about 0.05 wt. % to about 3 wt. %, about 0.05 wt. % to about 2 wt. %, about 0.05 wt. % to about 1.5 wt. %, about 0.05 wt. % to about 1 wt. %, about 0.05 wt. % to about 0.5 wt. %, about 0.05 wt. % to about 5 wt. %, about 0.05 wt. % to about 4 wt. %, about 0.05 wt. % to about 3 wt. %, about 0.05 wt. % to about 2 wt. %, about 0.05 wt. % to about 1.5 wt. %, about 0.05 wt. % to about 1 wt. %, about 0.05 wt. % to about 0.5 wt. %, about 0.1 wt. % to about 5 wt. %, about 0.1 wt. % to about 4 wt. %, about 0.1 wt. % to about 3 wt. %, about 0.1 wt. % to about 2 wt. %, about 0.1 wt. % to about 1.5 wt. %, about 0.1 wt. % to about 1 wt. %, about 0.1 wt. % to about 0.5 wt. %, about 0.5 wt. % to about 5 wt. %, about 0.5 wt. % to about 4 wt. %, about 0.5 wt. % to about 3 wt. %, about 0.5 wt. % to about 2 wt. %, about 0.5 wt. % to about 1.5 wt. %, or about 0.5 wt. % to about 1 wt. %. In some embodiments, the polishing composition comprises about 0.001 wt. % to about 2 wt. % of the buffering agent. In certain embodiments, the polishing composition comprises about 0.001 wt. % to about 0.5 wt. % of the buffering agent.

The chemical-mechanical polishing composition comprises water. The water can be any suitable water including, for example, deionized water or distilled water. In some embodiments, the chemical-mechanical polishing composition can further comprise one or more organic solvents in combination with the water. For example, the polishing composition can further comprise a hydroxylic solvent such as methanol or ethanol, a ketonic solvent, an amide solvent, a sulfoxide solvent, and the like. In certain embodiments, the chemical-mechanical polishing composition comprises pure water.

The chemical-mechanical polishing composition has a pH of about 1 to about 6 at the point-of-use. Thus, the chemical-mechanical polishing composition can have a pH of about 1 or more, e.g., about 1.5 or more, about 2 or more, about 2.2 or more, about 2.4 or more, about 2.6 or more, about 2.8 or more, about 3 or more, about 3.2 or more, about 3.4 or more, about 3.6 or more, about 3.8 or more, or about 4 or more. Alternatively, or in addition, the chemical-mechanical polishing composition can have a pH of about 6 or less, e.g., about 5.5 or less, about 5 or less, about 4.8 or less, about 4.6 or less, about 4.4 or less, about 4.2 or less, or about 4 or less. Thus, the chemical-mechanical polishing composition can have a pH bounded by any two of the aforementioned endpoints. For example the chemical-mechanical polishing composition can have a pH of about 1 to about 5.5, e.g., about 1 to about 5, about 2 to about 6, about 2 to about 5, about 2.2 to about 5, about 2.2 to about 4.8, about 2.4 to about 4.8, about 2.4 to about 4.6, about 2.4 to about 4.4, about 2.4 to about 4.2, about 1 to about 4, about 1.5 to about 4, about 2 to about 4, about 3 to about 6, about 3.5 to about 6, about 4 to about 6, about 3 to about 5, or about 4 to about 5 at the point-of-use. In some embodiments, the polishing composition has a pH of about 3 to about 6. In certain embodiments, the polishing composition has a pH of about 4 to about 6.

The chemical-mechanical polishing composition can comprise one or more compounds capable of adjusting (i.e., that adjust) the pH of the polishing composition (i.e., pH adjusting compounds). The pH of the polishing composition can be adjusted using any suitable compound capable of adjusting the pH of the polishing composition. The pH adjusting compound desirably is water-soluble and compatible with the other components of the polishing composition. Non-limiting examples of suitable acids for adjusting the pH of the polishing composition include nitric acid, sulfuric acid, phosphoric acid, and organic acids such as formic acid and acetic acid. Non-limiting examples of suitable bases for adjusting the pH of the polishing composition include sodium hydroxide, potassium hydroxide, and ammonium hydroxide. In some embodiments, the buffering agent is sufficient to adjust the pH of the polishing composition.

In some embodiments, the chemical-mechanical polishing composition further comprises one or more additives such as, for example, conditioners, acids (e.g., sulfonic acids), complexing agents (e.g., anionic polymeric complexing agents), chelating agents, biocides, scale inhibitors, dispersants, and/or conductivity adjustors.

In some embodiments, the chemical-mechanical polishing composition further comprises a biocide. A biocide, when present, can be any suitable biocide and can be present in the polishing composition in any suitable amount. For example, the biocide can be an isothiazolinone-based biocide such as Kordek MLX™ (DuPont, Wilmington, DE). In certain embodiments, the biocide is 5-chloro-2-methyl-4-isothiazolin-3-one, 2-methyl-4-isothiazolin-3-one, benzisothiazolinone, 1,2-benzisothiazol-3 [2H]-one, methylisothiazolinone, methylchloroisothiazolinone, or a combination thereof. The biocide can be present in the polishing composition at a concentration of about 1 ppm to about 750 ppm, preferably about 10 ppm to about 200 ppm. In some embodiments, the biocide is benzisothiazolinone.

The chemical-mechanical polishing composition can have any suitable conductivity. Accordingly, the polishing composition can have a conductivity of about 50 μS/cm or more, for example, about 75 μS/cm or more, about 100 μS/cm or more, about 150 μS/cm or more, or about 200 μS/cm or more. Alternatively, or in addition, the polishing composition can have a conductivity of about 1000 μS/cm or less, for example, about 900 μS/cm or less, about 800 μS/cm or less, about 700 μS/cm or less, about 600 μS/cm or less, about 500 μS/cm or less, about 400 μS/cm or less, about 300 μS/cm or less, or about 200 μS/cm or less. Thus, the polishing composition can have a conductivity bounded by any two of the aforementioned endpoints.

For example, the polishing composition can have a conductivity of about 50 μS/cm to about 1000 μS/cm, about 50 μS/cm to about 900 μS/cm, about 50 μS/cm to about 800 μS/cm, about 50 μS/cm to about 700 μS/cm, about 50 μS/cm to about 600 μS/cm, about 50 μS/cm to about 500 μS/cm, about 50 μS/cm to about 400 μS/cm, about 50 μS/cm to about 300 μS/cm, about 50 μS/cm to about 200 μS/cm, about 75 μS/cm to about 1000 μS/cm, about 75 μS/cm to about 900 μS/cm, about 75 μS/cm to about 800 μS/cm, about 75 μS/cm to about 700 μS/cm, about 75 μS/cm to about 600 μS/cm, about 75 μS/cm to about 500 μS/cm, about 75 μS/cm to about 400 μS/cm, about 75 μS/cm to about 300 μS/cm, about 75 μS/cm to about 200 μS/cm, about 100 μS/cm to about 1000 μS/cm, about 100 μS/cm to about 900 μS/cm, about 100 μS/cm to about 800 μS/cm, about 100 μS/cm to about 700 μS/cm, about 100 μS/cm to about 600 μS/cm, about 100 μS/cm to about 500 μS/cm, about 100 μS/cm to about 400 μS/cm, about 100 μS/cm to about 300 μS/cm, about 100 μS/cm to about 200 μS/cm, about 150 μS/cm to about 1000 μS/cm, about 150 μS/cm to about 900 μS/cm, about 150 μS/cm to about 800 μS/cm, about 150 μS/cm to about 700 μS/cm, about 150 μS/cm to about 600 μS/cm, about 150 μS/cm to about 500 μS/cm, about 150 μS/cm to about 400 μS/cm, about 150 μS/cm to about 300 μS/cm, about 200 μS/cm to about 1000 μS/cm, about 200 μS/cm to about 900 μS/cm, about 200 μS/cm to about 800 μS/cm, about 200 μS/cm to about 700 μS/cm, about 200 μS/cm to about 600 μS/cm, about 200 μS/cm to about 500 μS/cm, about 200 μS/cm to about 400 μS/cm, or about 200 μS/cm to about 300 μS/cm. In some embodiments, the polishing composition has a conductivity of about 200 μS/cm to about 400 μS/cm. In certain embodiments, the polishing composition has a conductivity of about 200 μS/cm to about 300 μS/cm.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6 to about 10, (b) a cationic polymer, (c) a buffering agent, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6.5 to about 10, (b) a cationic polymer, (c) a buffering agent, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 7 to about 9, (b) a cationic polymer, (c) a buffering agent, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6 to about 10, (b) a cationic polymer, (c) acetic acid, and (d) water, wherein the polishing composition has a pH of about 1 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6 to about 10, (b) a cationic polymer, (c) acetic acid, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6.5 to about 10, (b) a cationic polymer, (c) acetic acid, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 7 to about 9, (b) a cationic polymer, (c) acetic acid, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6 to about 10, (b) poly(diallyldimethylammonium) chloride (polyDADMAC) or a salt thereof, (c) a buffering agent, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6.5 to about 10, (b) poly(diallyldimethylammonium) chloride (polyDADMAC) or a salt thereof, (c) a buffering agent, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 7 to about 9, (b) poly(diallyldimethylammonium) chloride (polyDADMAC) or a salt thereof, (c) a buffering agent, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6 to about 10, (b) poly(diallyldimethylammonium) chloride (polyDADMAC) or a salt thereof, (c) acetic acid, and (d) water, wherein the polishing composition has a pH of about 1 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6 to about 10, (b) poly(diallyldimethylammonium) chloride (polyDADMAC) or a salt thereof, (c) acetic acid, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 6.5 to about 10, (b) poly(diallyldimethylammonium) chloride (polyDADMAC) or a salt thereof, (c) acetic acid, and (d) water, wherein the polishing composition has a pH of about 4 to about 6.

In some embodiments, the chemical-mechanical polishing composition comprises (a) colloidal silica particles, wherein the colloidal silica particles are surface-modified with an aminosilane compound, and wherein the colloidal silica particles have an isoelectric point of about 7 to about 9, (b) poly(diallyldimethylammonium) chloride (polyDADMAC) or a salt thereof, (c) acetic acid, and (d) water, wherein the polishing composition has a pH of about 4 to about 6.

The chemical-mechanical polishing composition can be produced by any suitable technique, many of which are known to those skilled in the art. The polishing composition can be prepared in a batch or continuous process. Generally, the polishing composition is prepared by combining the components of the polishing composition in any order. The term “component” as used herein includes individual ingredients (e.g., surface-modified colloidal silica particles, cationic polymer, buffering agent, optional biocide, and/or any other optional additive, etc.) as well as any combination of ingredients (e.g., surface-modified colloidal silica particles, cationic polymer, buffering agent, optional biocide, and/or any other optional additive, etc.).

For example, the polishing composition can be prepared by (i) providing all or a portion of the liquid carrier, (ii) dispersing the surface-modified colloidal silica particles, cationic polymer, buffering agent, optional biocide, and/or any other optional additive, etc., using any suitable means for preparing such a dispersion, (iii) adjusting the pH of the dispersion as appropriate, and (iv) optionally adding suitable amounts of any other optional components and/or additives to the mixture.

Alternatively, the polishing composition can be prepared by (i) providing one or more components (e.g., cationic polymer, buffering agent, optional biocide, and/or any other optional additive, etc.) in a surface-modified colloidal silica particle slurry, (ii) providing one or more components (e.g., cationic polymer, buffering agent, optional biocide, and/or any other optional additive, etc.) in an additive solution, (iii) combining the surface-modified colloidal silica particle slurry and the additive solution to form a mixture, (iv) optionally adding suitable amounts of any other optional additives to the mixture, and (v) adjusting the pH of the mixture as appropriate.

The polishing composition can be supplied as a one-package system comprising surface-modified colloidal silica particles, cationic polymer, buffering agent, optional biocide, and/or any other optional additive, and water. Alternatively, the polishing composition of the invention can be supplied as a two-package system comprising a surface-modified colloidal silica particle slurry in a first package and an additive solution in a second package, wherein the surface-modified colloidal silica particle slurry consists essentially of, or consists of, surface-modified colloidal silica particles and water, and wherein the additive solution consists essentially of, or consists of, cationic polymer, buffering agent, biocide, and/or any other optional additive. The two-package system allows for the adjustment of polishing composition characteristics by changing the blending ratio of the two packages, i.e., the surface-modified colloidal silica particle slurry and the additive solution.

Various methods can be employed to utilize such a two-package polishing system. For example, the surface-modified colloidal silica particle slurry and additive solution can be delivered to the polishing table by different pipes that are joined and connected at the outlet of supply piping. The surface-modified colloidal silica particle slurry and additive solution can be mixed shortly or immediately before polishing, or can be supplied simultaneously on the polishing table. Furthermore, when mixing the two packages, deionized water can be added, as desired, to adjust the polishing composition and resulting substrate polishing characteristics.

Similarly, a three-, four-, or more package system can be utilized in connection with the invention, wherein each of multiple containers contains different components of the inventive chemical-mechanical polishing composition, one or more optional components, and/or one or more of the same components in different concentrations.

In order to mix components contained in two or more storage devices to produce the polishing composition at or near the point-of-use, the storage devices typically are provided with one or more flow lines leading from each storage device to the point-of-use of the polishing composition (e.g., the platen, the polishing pad, or the substrate surface). As utilized herein, the term “point-of-use” refers to the point at which the polishing composition is applied to the substrate surface (e.g., the polishing pad or the substrate surface itself). By the term “flow line” is meant a path of flow from an individual storage container to the point-of-use of the component stored therein. The flow lines can each lead directly to the point-of-use, or two or more of the flow lines can be combined at any point into a single flow line that leads to the point-of-use. Furthermore, any of the flow lines (e.g., the individual flow lines or a combined flow line) can first lead to one or more other devices (e.g., pumping device, measuring device, mixing device, etc.) prior to reaching the point-of-use of the component(s).

The components of the polishing composition can be delivered to the point-of-use independently (e.g., the components are delivered to the substrate surface whereupon the components are mixed during the polishing process), or one or more of the components can be combined before delivery to the point-of-use, e.g., shortly or immediately before delivery to the point-of-use. Components are combined “immediately before delivery to the point-of-use” if the components are combined about 5 minutes or less prior to being added in mixed form onto the platen, for example, about 4 minutes or less, about 3 minutes or less, about 2 minutes or less, about 1 minute or less, about 45 seconds or less, about 30 seconds or less, about 10 seconds or less prior to being added in mixed form onto the platen, or simultaneously to the delivery of the components at the point-of-use (e.g., the components are combined at a dispenser). Components also are combined “immediately before delivery to the point-of-use” if the components are combined within 5 m of the point-of-use, such as within 1 m of the point-of-use or even within 10 cm of the point-of-use (e.g., within 1 cm of the point-of-use).

When two or more of the components of the polishing composition are combined prior to reaching the point-of-use, the components can be combined in the flow line and delivered to the point-of-use without the use of a mixing device. Alternatively, one or more of the flow lines can lead into a mixing device to facilitate the combination of two or more of the components. Any suitable mixing device can be used. For example, the mixing device can be a nozzle or jet (e.g., a high-pressure nozzle or jet) through which two or more of the components flow. Alternatively, the mixing device can be a container-type mixing device comprising one or more inlets by which two or more components of the polishing slurry are introduced to the mixer, and at least one outlet through which the mixed components exit the mixer to be delivered to the point-of-use, either directly or via other elements of the apparatus (e.g., via one or more flow lines). Furthermore, the mixing device can comprise more than one chamber, each chamber having at least one inlet and at least one outlet, wherein two or more components are combined in each chamber. If a container-type mixing device is used, the mixing device preferably comprises a mixing mechanism to further facilitate the combination of the components. Mixing mechanisms are generally known in the art and include stirrers, blenders, agitators, paddled baffles, gas sparger systems, vibrators, etc.

The polishing composition also can be provided as a concentrate which is intended to be diluted with an appropriate amount of water prior to use. In such an embodiment, the polishing composition concentrate comprises the components of the polishing composition in amounts such that, upon dilution of the concentrate with an appropriate amount of water, each component of the polishing composition will be present in the polishing composition in an amount within the appropriate range recited above for each component. For example, the surface-modified colloidal silica particles, cationic polymer, buffering agent, optional biocide, and/or any other optional additive can each be present in the concentrate in an amount that is about 2 times (e.g., about 3 times, about 4 times, or about 5 times) greater than the concentration recited above for each component so that, when the concentrate is diluted with an equal volume of water (e.g., 2 equal volumes water, 3 equal volumes of water, or 4 equal volumes of water, respectively), each component will be present in the polishing composition in an amount within the ranges set forth above for each component.

The invention further provides a method of chemically-mechanically polishing a substrate comprising: (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) a cationic polymer, (c) a buffering agent, and (d) water, wherein the polishing composition has a pH of about 1 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) a cationic polymer, (c) a buffering agent, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6.5 to about 10, (b) a cationic polymer, (c) a buffering agent, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 7 to about 9, (b) a cationic polymer, (c) a buffering agent, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) a cationic polymer, (c) acetic acid, and (d) water, wherein the polishing composition has a pH of about 1 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) a cationic polymer, (c) acetic acid, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6.5 to about 10, (b) a cationic polymer, (c) acetic acid, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 7 to about 9, (b) a cationic polymer, (c) acetic acid, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The invention further provides a method of chemically-mechanically polishing a substrate comprising: (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) poly(diallyldimethylammonium) chloride (polyDADMAC) or a salt thereof, (c) a buffering agent, and (d) water, wherein the polishing composition has a pH of about 1 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) poly(diallyldimethylammonium) chloride (polyDADMAC) or a salt thereof, (c) a buffering agent, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6.5 to about 10, (b) poly(diallyldimethylammonium) chloride (polyDADMAC) or a salt thereof, (c) a buffering agent, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 7 to about 9, (b) poly(diallyldimethylammonium) chloride (polyDADMAC) or a salt thereof, (c) a buffering agent, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) poly(diallyldimethylammonium) chloride (polyDADMAC) or a salt thereof, (c) acetic acid, and (d) water, wherein the polishing composition has a pH of about 1 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6 to about 10, (b) poly(diallyldimethylammonium) chloride (polyDADMAC) or a salt thereof, (c) acetic acid, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 6.5 to about 10, (b) poly(diallyldimethylammonium) chloride (polyDADMAC) or a salt thereof, (c) acetic acid, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

In some embodiments, the method of chemically-mechanically polishing a substrate comprises (i) providing a substrate, (ii) providing a polishing pad, (iii) providing a chemical-mechanical polishing composition comprising: (a) colloidal silica particles, wherein the colloidal silica particles are surface-modified with an aminosilane compound, and wherein the colloidal silica particles have an isoelectric point of about 7 to about 9, (b) poly(diallyldimethylammonium) chloride (polyDADMAC) or a salt thereof, (c) acetic acid, and (d) water, wherein the polishing composition has a pH of about 4 to about 6, (iv) contacting the substrate with the polishing pad and the chemical-mechanical polishing composition, and (v) moving the polishing pad and the chemical-mechanical polishing composition relative to the substrate to abrade at least a portion of the substrate to polish the substrate.

The chemical-mechanical polishing composition can be used to polish any suitable substrate and is especially useful for polishing substrates comprising at least one layer (typically a surface layer) comprised of silicon oxide, polysilicon, or amorphous silicon. Suitable substrates include wafers used in the semiconductor industry. The wafers typically comprise or consist of, for example, a metal, metal oxide, metal nitride (e.g., silicon nitride), metal composite, metal alloy, a low dielectric material, or combinations thereof. The method of the invention is particularly useful for polishing substrates comprising silicon oxide, polysilicon, and/or amorphous silicon, i.e., polishing substrates comprising any one, two, or three of silicon oxide, polysilicon, and/or amorphous silicon. In some embodiments, the polishing substrate comprises polysilicon and/or amorphous silicon in combination with silicon oxide.

In some embodiments, the substrate comprises silicon oxide on a surface of the substrate, and at least a portion of the silicon oxide on a surface of the substrate is abraded at a silicon oxide removal rate (Å/min) to polish the substrate. The silicon oxide can be any suitable silicon oxide, many forms of which are known in the art. Suitable types of silicon oxide include, but are not limited to, silicon oxide films derived from tetraethyl orthosilicate (TEOS), borophosphosilicate glass (BPSG), plasma enhanced tetraethyl orthosilicate (PETEOS), thermal oxide, undoped silicate glass, and high-density plasma (HDP) oxide. The chemical-mechanical polishing composition of the invention desirably provides for a tunable removal rate of silicon oxide. In that respect, according to a method of the invention, as the amount of cationic polymer increases, the removal rate of the silicon oxide decreases such that the silicon oxide removal rate can be tuned. Thus, when polishing substrates comprising silicon oxide in accordance with an embodiment of the invention, the polishing composition desirably exhibits a removal rate of the silicon oxide of about 400 Å/min or higher, for example, about 500 Å/min or higher, about 600 Å/min or higher, about 700 Å/min or higher, about 800 Å/min or higher, about 900 Å/min or higher, about 1,000 Å/min or higher, about 1,100 Å/min or higher, about 1,200 Å/min or higher, about 1,500 Å/min or higher, about 2,000 Å/min or higher, about 3,000 Å/min or higher, or about 4,000 Å/min or higher. Alternatively, or additionally, when polishing substrates comprising silicon oxide in accordance with an embodiment of the invention, the polishing composition desirably exhibits a removal rate of the silicon oxide of about 400 Å/min or less, for example, about 500 Å/min or less, about 600 Å/min or less, about 700 Å/min or less, about 800 Å/min or less, about 900 Å/min or less, about 1,000 Å/min or less, about 1,100 Å/min or less, about 1,200 Å/min or less, about 1,500 Å/min or less, about 2,000 Å/min or less, about 3,000 Å/min or less, or about 4,000 Å/min or less. In certain embodiments, silicon oxide removal rate is bounded by any two of the aforementioned endpoints.

In some embodiments, the substrate comprises polysilicon on a surface of the substrate, and at least a portion of the polysilicon on a surface of the substrate is abraded at a polysilicon removal rate (Å/min) to polish the substrate. The polysilicon can have any suitable phase, and can be amorphous, crystalline, or a combination thereof. The chemical-mechanical polishing composition of the invention desirably provides for a tunable removal rate of polysilicon. In that respect, according to a method of the invention, as the amount of cationic polymer increases, the removal rate of the polysilicon increases such that the polysilicon removal rate can be tuned. Thus, when polishing substrates comprising polysilicon in accordance with an embodiment of the invention, the polishing composition desirably exhibits a removal rate of the polysilicon of about 100 Å/min or higher, for example, about 200 Å/min or higher, about 300 Å/min or higher, about 400 Å/min or higher, about 500 Å/min or higher, about 600 Å/min or higher, about 700 Å/min or higher, about 800 Å/min or higher, about 900 Å/min or higher, or about 1,000 Å/min or higher. Alternatively, or additionally, when polishing substrates comprising polysilicon in accordance with an embodiment of the invention, the polishing composition desirably exhibits a removal rate of the polysilicon of about 1,000 Å/min or less, for example, about 1,100 Å/min or less, about 1,200 Å/min or less, about 1,500 Å/min or less, about 2,000 Å/min or less, about 3,000 Å/min or less, or about 4,000 Å/min or less. In certain embodiments, the polysilicon removal rate is bounded by any two of the aforementioned endpoints. For example, the polishing composition can exhibit a removal rate of the polysilicon of about 500 Å/min to about 3,000 Å/min, about 500 Å/min to about 2,000 Å/min, about 1,000 Å/min to about 3,000 Å/min, or about 1,000 Å/min to about 2,000 Å/min.

In some embodiments, when the inventive polishing composition is used to polish a substrate comprising a silicon oxide layer and a polysilicon layer, the removal rates of silicon oxide and polysilicon are tunable such that the polishing composition can (i) exhibit selectivity for the polishing of the silicon oxide layer over the polysilicon layer, (ii) exhibit selectivity for the polishing of the polysilicon layer over the silicon oxide layer, or (iii) exhibit about the same removal rate for the silicon oxide layer and the polysilicon layer. In certain embodiments, the polysilicon removal rate is greater than the silicon oxide removal rate. For example, the polysilicon removal rate can be at least 5 times greater than the silicon oxide removal rate or the polysilicon removal rate can be at least 10 times greater than the silicon oxide removal rate.

In some embodiments, the substrate comprises amorphous silicon on a surface of the substrate, and at least a portion of the amorphous silicon on a surface of the substrate is abraded at an amorphous silicon removal rate (Å/min) to polish the substrate. The amorphous silicon can be any suitable amorphous silicon, many forms of which are known in the art. The chemical-mechanical polishing composition of the invention desirably provides for a tunable removal rate of amorphous silicon. In that respect, according to a method of the invention, as the amount of cationic polymer increases, the removal rate of the amorphous silicon increases such that the amorphous silicon removal rate can be tuned. Thus, when polishing substrates comprising amorphous silicon in accordance with an embodiment of the invention, the polishing composition desirably exhibits a removal rate of the amorphous silicon of about 100 Å/min or higher, for example, about 200 Å/min or higher, about 300 Å/min or higher, about 400 Å/min or higher, about 500 Å/min or higher, about 600 Å/min or higher, about 700 Å/min or higher, about 800 Å/min or higher, about 900 Å/min or higher, or about 1,000 Å/min or higher. Alternatively, or additionally, when polishing substrates comprising amorphous silicon in accordance with an embodiment of the invention, the polishing composition desirably exhibits a removal rate of the amorphous silicon of about 1,000 Å/min or less, for example, about 1,100 Å/min or less, about 1,200 Å/min or less, about 1,500 Å/min or less, about 2,000 Å/min or less, about 3,000 Å/min or less, or about 4,000 Å/min or less. In certain embodiments, the amorphous silicon removal rate is bounded by any two of the aforementioned endpoints. For example, the polishing composition can exhibit a removal rate of the amorphous silicon of about 500 Å/min to about 3,000 Å/min, about 500 Å/min to about 2,000 Å/min, about 1,000 Å/min to about 3,000 Å/min, or about 1,000 Å/min to about 2,000 Å/min.

In some embodiments, when the inventive polishing composition is used to polish a substrate comprising a silicon oxide layer and an amorphous silicon layer, the removal rates of silicon oxide and amorphous silicon are tunable such that the polishing composition can (i) exhibit selectivity for the polishing of the silicon oxide layer over the amorphous silicon layer, (ii) exhibit selectivity for the polishing of the amorphous silicon layer over the silicon oxide layer, or (iii) exhibit about the same removal rate for the silicon oxide layer and the amorphous silicon layer. In certain embodiments, the amorphous silicon removal rate is greater than the silicon oxide removal rate. For example, the amorphous silicon removal rate can be at least 5 times greater than the silicon oxide removal rate or the amorphous silicon removal rate can be at least 10 times greater than the silicon oxide removal rate.

In some embodiments, the substrate comprises silicon nitride on a surface of the substrate, and at least a portion of the silicon nitride on a surface of the substrate is abraded at a silicon nitride removal rate (Å/min) to polish the substrate. The silicon nitride can be any suitable silicon nitride and can be applied to the surface by any suitable method (e.g., low pressure chemical vapor deposition (LPCVD) or plasma enhanced chemical vapor deposition (PECVD)). The chemical-mechanical polishing composition of the invention desirably exhibits a low removal rate when polishing a substrate comprising silicon nitride according to a method of the invention. For example, when polishing substrates comprising silicon nitride in accordance with an embodiment of the invention, the polishing composition desirably exhibits a removal rate of the silicon nitride of about 200 Å/min or lower, for example, about 150 Å/min or lower, about 100 Å/min or lower, about 90 Å/min or lower, about 80 Å/min or lower, about 70 Å/min or lower, about 60 Å/min or lower, or about 50 Å/min or lower.

In some embodiments, the polishing composition of the invention desirably exhibits low particle defects when polishing a substrate, as determined by suitable techniques. Particle defects on a substrate polished with the inventive polishing composition can be determined by any suitable technique. For example, laser light scattering techniques, such as dark field normal beam composite (DCN) and dark field oblique beam composite (DCO), can be used to determine particle defects on polished substrates. Suitable instrumentation for evaluating particle defectivity is available from, for example, KLA-Tencor (e.g., SURFSCAN™ SPI instruments operating at a 120 nm threshold or at 160 nm threshold).

The chemical-mechanical polishing composition and method of the invention are particularly suited for use in conjunction with a chemical-mechanical polishing apparatus. Typically, the apparatus comprises a platen, which, when in use, is in motion and has a velocity that results from orbital, linear, or circular motion, a polishing pad in contact with the platen and moving with the platen when in motion, and a carrier that holds a substrate to be polished by contacting and moving the substrate relative to the surface of the polishing pad. The polishing of the substrate takes place by the substrate being placed in contact with the polishing pad and the polishing composition of the invention, and then the polishing pad moving relative to the substrate, so as to abrade at least a portion of the substrate to polish the substrate.

A substrate can be polished with the chemical-mechanical polishing composition using any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, coformed products thereof, and mixtures thereof. Soft polyurethane polishing pads are particularly useful in conjunction with the inventive polishing method. Typical pads include but are not limited to SURFIN™ 000, SURFIN™ SSW1, SPM3100 Eminess Technologies), POLITEX™ commercially available from Dow Chemical Company (Newark, DE), POLYPAS™ 27 or Fujibo H7000 commercially available from Fujibo (Osaka, JP), and EPIC™ D100 pads or NEXPLANAR™ E6088 commercially available from Cabot Microelectronics (Aurora, IL).

Desirably, the chemical-mechanical polishing apparatus further comprises an in situ polishing endpoint detection system, many of which are known in the art. Techniques for inspecting and monitoring the polishing process by analyzing light or other radiation reflected from a surface of the substrate being polished are known in the art. Such methods are described, for example, in U.S. Pat. Nos. 5,196,353, 5,433,651, 5,609,511. U.S. Pat. Nos. 5,643,046, 5,658,183, 5,730,642, 5,838,447, 5,872,633. U.S. Pat. Nos. 5,893,796, 5,949,927, and 5,964,643. Desirably, the inspection or monitoring of the progress of the polishing process with respect to a substrate being polished enables the determination of the polishing end-point, i.e., the determination of when to terminate the polishing process with respect to a particular substrate.

Aspects, including embodiments, of the invention described herein may be beneficial alone or in combination, with one or more other aspects or embodiments. Without limiting the foregoing description, certain non-limiting embodiments of the disclosure numbered 1-63 are provided below. As will be apparent to those of skill in the art upon reading this disclosure, each of the individually numbered embodiments may be used or combined with any of the preceding or following individually numbered embodiments. This is intended to provide support for all such combinations of embodiments and is not limited to combinations of embodiments explicitly provided below:

### EMBODIMENTS

(1) In embodiment (1) is presented a chemical-mechanical polishing composition comprising:
(a) colloidal silica particles, wherein the colloidal silica particles are surface-modified with an aminosilane compound, and wherein the colloidal silica particles have an isoelectric point of about 6 to about 10,
(b) a cationic polymer,
(c) a buffering agent, and
(d) water,
   wherein the polishing composition has a pH of about 1 to about 6.

(2) In embodiment (2) is presented the polishing composition of embodiment (1), wherein the polishing composition has a pH of about 3 to about 6.

(3) In embodiment (3) is presented the polishing composition of embodiment (1) or embodiment (2), wherein the polishing composition has a pH of about 4 to about 6.

(4) In embodiment (4) is presented the polishing composition of any one of embodiments (1)-(3), wherein the polishing composition comprises about 0.001 wt. % to about 10 wt. % of the colloidal silica particles.

(5) In embodiment (5) is presented the polishing composition of any one of embodiments (1)-(4), wherein the polishing composition comprises about 0.1 wt. % to about 1 wt. % of the colloidal silica particles.

(6) In embodiment (6) is presented the polishing composition of any one of embodiments (1)-(5), wherein the colloidal silica particles have an isoelectric point of about 6.2 to about 10.

(7) In embodiment (7) is presented the polishing composition of any one of embodiments (1)-(6), wherein the colloidal silica particles have an isoelectric point of about 6.5 to about 9.

(8) In embodiment (8) is presented the polishing composition of any one of embodiments (1)-(7), wherein the colloidal silica particles have an average surface modification level of the aminosilane compound of from about 5% to about 50%.

(9) In embodiment (9) is presented the polishing composition of any one of embodiments (1)-(8), wherein the colloidal silica particles have an average surface modification level of the aminosilane compound from about 10% to about 50%.

(10) In embodiment (10) is presented the polishing composition of any one of embodiments (1)-(9), wherein the aminosilane compound is a monopodal aminosilane compound.

(11) In embodiment (11) is presented the polishing composition of any one of embodiments (1)-(9), wherein the aminosilane compound is a multipodal aminosilane compound.

(12) In embodiment (12) is presented the polishing composition of any one of embodiments (1)-(11), wherein the colloidal silica particles have a zeta potential in the polishing composition of about 20 mV to about 50 mV.

(13) In embodiment (13) is presented the polishing composition of any one of embodiments (1)-(12), wherein the colloidal silica particles have a zeta potential in the polishing composition of about 30 mV to about 40 mV.

(14) In embodiment (14) is presented the polishing composition of any one of embodiments (1)-(13), wherein the colloidal silica particles have a D50 particle size in a range from about 30 nm to about 80 nm.

(15) In embodiment (15) is presented the polishing composition of any one of embodiments (1)-(14), wherein the colloidal silica particles have a D50 particle size in a range from about 45 nm to about 55 nm.

(16) In embodiment (16) is presented the polishing composition of any one of embodiments (1)-(15), wherein the colloidal silica particles have an aspect ratio of greater than about 1.2.

(17) In embodiment (17) is presented the polishing composition of any one of embodiments (1)-(16), wherein the colloidal silica particles have a Brunauer-Emmett-Teller (BET) surface area from about 60 m²/g to about 120 m²/g.

(18) In embodiment (18) is presented the polishing composition of any one of embodiments (1)-(17), wherein the cationic polymer comprises polyethylenimine, poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly [bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof.

(19) In embodiment (19) is presented the polishing composition of any one of embodiments (1)-(18), wherein the cationic polymer is poly(diallyldimethylammonium) chloride (polyDADMAC) or a salt thereof.

(20) In embodiment (20) is presented the polishing composition of any one of embodiments (1)-(19), wherein the polishing composition comprises about 100 ppm to about 1000 ppm of the cationic polymer.

(21) In embodiment (21) is presented the polishing composition of any one of embodiments (1)-(20), wherein the polishing composition comprises about 200 ppm to about 500 ppm of the cationic polymer.

(22) In embodiment (22) is presented the polishing composition of any one of embodiments (1)-(21), wherein the buffering agent comprises an organic acid.

(23) In embodiment (23) is presented the polishing composition of any one of embodiments (1)-(22), wherein the buffering agent comprises formic acid, malonic acid, acetic acid, oxalic acid, citric acid, or a combination thereof.

(24) In embodiment (24) is presented the polishing composition of any one of embodiments (1)-(23), wherein the buffering agent comprises acetic acid.

(25) In embodiment (25) is presented the polishing composition of any one of embodiments (1)-(24), wherein the polishing composition further comprises a biocide.

(26) In embodiment (26) is presented the polishing composition of any one of embodiments (1)-(25), wherein the polishing composition has a conductivity of about 50 μS/cm to about 400 μS/cm.

(27) In embodiment (27) is presented the polishing composition of any one of embodiments (1)-(26), wherein the polishing composition has a conductivity of about 200 μS/cm to about 300 μS/cm.

(28) In embodiment (28) is presented a method of chemically-mechanically polishing a substrate comprising:
(i) providing a substrate,
(ii) providing a polishing pad,
(iii) providing a chemical-mechanical polishing composition comprising:
   (a) colloidal silica particles, wherein the colloidal silica particles are surface-modified with an aminosilane compound, and wherein the colloidal silica particles have an isoelectric point of about 6 to about 10,
   (b) a cationic polymer,
   (c) a buffering agent, and
   (d) water,
   wherein the polishing composition has a pH of about 1 to about 6,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

(29) In embodiment (29) is presented the method of embodiment (28), wherein the polishing composition has a pH of about 3 to about 6.

(30) In embodiment (30) is presented the method of embodiment (28) or embodiment (29), wherein the polishing composition has a pH of about 4 to about 6.

(31) In embodiment (31) is presented the method of any one of embodiments (28)-(30), wherein the polishing composition comprises about 0.001 wt. % to about 10 wt. % of the colloidal silica particles.

(32) In embodiment (32) is presented the method of any one of embodiments (28)-(31), wherein the polishing composition comprises about 0.1 wt. % to about 1 wt. % of the colloidal silica particles.

(33) In embodiment (33) is presented the method of any one of embodiments (28)-(32), wherein the colloidal silica particles have an isoelectric point of about 6.2 to about 10.

(34) In embodiment (34) is presented the method of any one of embodiments (28)-(33), wherein the colloidal silica particles have an isoelectric point of about 6.5 to about 9.

(35) In embodiment (35) is presented the method of any one of embodiments (28)-(34), wherein the colloidal silica particles have an average surface modification level of the aminosilane compound of from about 5% to about 50%.

(36) In embodiment (36) is presented the method of any one of embodiments (28)-(35), wherein the colloidal silica particles have an average surface modification level of the aminosilane compound of from about 10% to about 50%.

(37) In embodiment (37) is presented the method of any one of embodiments (28)-(36), wherein the aminosilane compound is a monopodal aminosilane compound.

(38) In embodiment (38) is presented the method of any one of embodiments (28)-(37), wherein the aminosilane compound is a multipodal aminosilane compound.

(39) In embodiment (39) is presented the method of any one of embodiments (28)-(38), wherein the colloidal silica particles have a zeta potential in the polishing composition of about 20 mV to about 50 mV.

(40) In embodiment (40) is presented the method of any one of embodiments (28)-(39), wherein the colloidal silica particles have a zeta potential in the polishing composition of about 30 mV to about 40 mV.

(41) In embodiment (41) is presented the method of any one of embodiments (28)-(40), wherein the colloidal silica particles have a D50 particle size in a range from about 30 nm to about 80 nm.

(42) In embodiment (42) is presented the method of any one of embodiments (28)-(41), wherein the colloidal silica particles have a D50 particle size in a range from about 45 nm to about 55 nm.

(43) In embodiment (43) is presented the method of any one of embodiments (28)-(42), wherein the colloidal silica particles have an aspect ratio of greater than about 1.2.

(44) In embodiment (44) is presented the method of any one of embodiments (24)-(43), wherein the colloidal silica particles have a Brunauer-Emmett-Teller (BET) surface area from about 60 m²/g to about 120 m²/g.

(45) In embodiment (45) is presented the method of any one of embodiments (28)-(44), wherein the cationic polymer comprises polyethylenimine, poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly [bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof.

(46) In embodiment (46) is presented the method of any one of embodiments (28)-(45), wherein the cationic polymer is poly(diallyldimethylammonium) chloride (polyDADMAC) or a salt thereof.

(47) In embodiment (47) is presented the method of any one of embodiments (28)-(46), wherein the polishing composition comprises about 100 ppm to about 1000 ppm of the cationic polymer.

(48) In embodiment (48) is presented the method of any one of embodiments (28)-(47), wherein the polishing composition comprises about 200 ppm to about 500 ppm of the cationic polymer.

(49) In embodiment (49) is presented the method of any one of embodiments (28)-(48), wherein the buffering agent comprises an organic acid.

(50) In embodiment (50) is presented the method of any one of embodiments (28)-(49), wherein the buffering agent comprises formic acid, malonic acid, acetic acid, oxalic acid, citric acid, or a combination thereof.

(51) In embodiment (51) is presented the method of any one of embodiments (28)-(50), wherein the buffering agent comprises acetic acid.

(52) In embodiment (52) is presented the method of any one of embodiments (28)-(51), wherein the polishing composition further comprises a biocide.

(53) In embodiment (53) is presented the method of any one of embodiments (28)-(52), wherein the polishing composition has a conductivity of about 50 μS/cm to about 400 μS/cm.

(54) In embodiment (54) is presented the method of any one of embodiments (28)-(53), wherein the polishing composition has a conductivity of about 200 μS/cm to about 300 μS/cm.

(55) In embodiment (55) is presented the method of any one of embodiments (28)-(54), wherein the substrate comprises silicon oxide on a surface of the substrate, and wherein at least a portion of the silicon oxide on a surface of the substrate is abraded at a silicon oxide removal rate (Å/min) to polish the substrate.

(56) In embodiment (56) is presented the method of any one of embodiments (28)-(55), wherein the substrate comprises polysilicon on a surface of the substrate, and wherein at least a portion of the polysilicon on a surface of the substrate is abraded at a polysilicon removal rate (Å/min) to polish the substrate.

(57) In embodiment (57) is presented the method of any one of embodiments (28)-(56), wherein the substrate comprises silicon oxide on a surface of the substrate, wherein at least a portion of the silicon oxide on a surface of the substrate is abraded at a silicon oxide removal rate (Å/min) to polish the substrate, and wherein the substrate comprises polysilicon on a surface of the substrate, wherein at least a portion of the polysilicon on a surface of the substrate is abraded at a polysilicon removal rate (Å/min) to polish the substrate, and wherein the polysilicon removal rate is greater than the silicon oxide removal rate.

(58) In embodiment (58) is presented the method of embodiment (57), wherein the polysilicon removal rate is at least 5 times greater than the silicon oxide removal rate.

(59) In embodiment (59) is presented the method of embodiment (57), wherein the polysilicon removal rate is at least 10 times greater than the silicon oxide removal rate.

(60) In embodiment (60) is presented the method of any one of embodiments (28)-(59), wherein the substrate comprises amorphous silicon on a surface of the substrate, and wherein at least a portion of the amorphous silicon on a surface of the substrate is abraded at an amorphous silicon removal rate (Å/min) to polish the substrate.

(61) In embodiment (61) is presented the method of any one of embodiments (28)-(60), wherein at least a portion of the silicon oxide on a surface of the substrate is abraded at a silicon oxide removal rate (Å/min) to polish the substrate, and wherein the substrate comprises amorphous silicon on a surface of the substrate, wherein at least a portion of the amorphous silicon on a surface of the substrate is abraded at an amorphous silicon removal rate (Å/min) to polish the substrate, and wherein the amorphous silicon removal rate is greater than the silicon oxide removal rate.

(62) In embodiment (62) is presented the method of embodiment (61), wherein the amorphous silicon removal rate is at least 5 times greater than the silicon oxide removal rate.

(63) In embodiment (63) is presented the method of embodiment (61), wherein the amorphous silicon removal rate is at least 10 times greater than the silicon oxide removal rate.

### EXAMPLES

These following examples further illustrate the invention but, of course, should not be construed as in any way limiting its scope.

The following abbreviations are used throughout the Examples: removal rate (RR); tetraethyl orthosilicate (TEOS); polysilicon (Poly); silicon nitride (SiN); and amorphous silicon (A-Si).

### Example 1

This example demonstrates the effect of cationic polymer (i.e., poly(diallyldimethylammonium) chloride (polyDADMAC)) concentration on the polishing performance provided by a polishing composition prepared according to the invention.

Polishing Compositions 1A-1F, used in this example, were prepared by combining 2.0 wt. % surface-modified colloidal silica particles (i.e., bipodal aminosilane-modified), 0.008 wt. % acetic acid, 66.6 ppm isothiazolinone-based biocide Kordek MLX™ (DuPont, Wilmington, DE), and polyDADMAC in the amounts set forth in Table 1, and the pH of each polishing composition was adjusted to 4.7.

TABLE 1
Polishing Compositions 1A-1F

| | polyDADMAC |
|---|---|
| | Concentration |
| | (ppm) |
| Polishing | 0 |
| Composition 1A | |
| (Comparative) | |
| Polishing | 20 |
| Composition 1B | |
| (Inventive) | |
| Polishing | 50 |
| Composition 1C | |
| (Inventive) | |
| Polishing | 100 |
| Composition 1D | |
| (Inventive) | |
| Polishing | 200 |
| Composition 1E | |
| (Inventive) | |
| Polishing | 500 |
| Composition 1F | |
| (Inventive) | |

Wafer coupons comprising TEOS, Poly, SiN, or A-Si were each polished under identical conditions using a Logitech benchtop polishing machine at 3 PSI (20.55 kPa) downforce using a NEXPLANAR™ U5050 pad commercially available from CMC Materials Inc. (Aurora, IL) conditioned with a product commercially identified as A189L (3M, St. Paul, MN). Logitech polishing parameters were as follows: head speed=93 rpm, platen speed=87 rpm, total flow rate=50 mL/min. Removal rates were calculated by measuring the film thickness, using spectroscopic elipsometry, and subtracting the final thickness from the initial thickness. Following polishing, the RR for TEOS, Poly, SiN, or A-Si were determined, and the results are set forth in Table 2.

TABLE 2
Polishing Removal Rates of Polishing Compositions 1A-1F

| | TEOS | A-Si | SiN | Poly | |
|---|---|---|---|---|---|
| | (Å/min) | (Å/min) | (Å/min) | (Å/min) | A-Si:TEOS |
| Polishing | 5844 | 2216 | 116 | 462 | 0.38 |
| Composition 1A | | | | | |
| (Comparative) | | | | | |
| Polishing | 4299 | 508 | 94 | 678 | 0.12 |
| Composition 1B | | | | | |
| (Inventive) | | | | | |
| Polishing | 3068 | 587 | 90 | 788 | 0.19 |
| Composition 1C | | | | | |
| (Inventive) | | | | | |
| Polishing | 686 | 997 | 70 | 1118 | 1.45 |
| Composition 1D | | | | | |
| (Inventive) | | | | | |
| Polishing | 44 | 1278 | 58 | 1372 | 29.05 |
| Composition 1E | | | | | |
| (Inventive) | | | | | |
| Polishing | 1 | 1175 | 40 | 1432 | 1175 |
| Composition 1F | | | | | |
| (Inventive) | | | | | |

As is apparent from the results set forth in Table 2, as the concentration of polyDADMAC in the polishing composition was increased, the TEOS removal rate decreased. In contrast, the SiN removal rate remained relatively constant despite the variation in polyDADMAC concentration, and the A-Si and Poly removal rates increased as the concentration of polyDADMAC in the polishing composition was increased. In addition, Table 2 shows that Inventive Polishing Compositions 1D, 1E, and 1F, containing 100 ppm, 200 ppm, and 500 ppm of polyDADMAC, respectively, exhibited a significantly higher selectivity for removal of A-Si over TEOS, when compared to Comparative Polishing Composition 1A.

### Example 2

This example demonstrates the effect of cationic polymer (i.e., poly(methacryloyloxyethyltrimethylammonium) chloride (polyMADQUAT)) concentration on the polishing performance provided by a polishing composition prepared according to the invention.

Polishing Compositions 2A-2F, used in this example, were prepared by combining 2.0 wt. % surface-modified colloidal silica particles (i.e., bipodal aminosilane-modified), 0.008 wt. % acetic acid, 66.6 ppm isothiazolinone-based biocide Kordek MLX™ (DuPont, Wilmington, DE), and polyMADQUAT in the amounts set forth in Table 3, and the pH of each polishing composition was adjusted to 4.7.

TABLE 3
Polishing Compositions 2A-2F

| | polyMADQUAT |
|---|---|
| | Concentration |
| | (ppm) |
| Polishing | 0 |
| Composition 2A | |
| (Comparative) | |
| Polishing | 20 |
| Composition 2B | |
| (Inventive) | |
| Polishing | 50 |
| Composition 2C | |
| (Inventive) | |
| Polishing | 100 |
| Composition 2D | |
| (Inventive) | |
| Polishing | 200 |
| Composition 2E | |
| (Inventive) | |
| Polishing | 500 |
| Composition 2F | |
| (Inventive) | |

Wafer coupons comprising TEOS, Poly, SiN, or A-Si were each polished under identical conditions using a Logitech benchtop polishing machine at 3 PSI (20.55 kPa) downforce using a NEXPLANAR™ U5050 pad commercially available from CMC Materials Inc. (Aurora, IL) conditioned with a product commercially identified as A189L (3M, St. Paul, MN). Logitech polishing parameters were as follows: head speed=93 rpm, platen speed=87 rpm, total flow rate=50 mL/min. Removal rates were calculated by measuring the film thickness, using spectroscopic elipsometry, and subtracting the final thickness from the initial thickness. Following polishing, the RR for TEOS, Poly, SiN, or A-Si were determined, and the results are set forth in Table 4.

TABLE 4
Polishing Removal Rates of Polishing Compositions 2A-2F

| | TEOS | A-Si | SiN | Poly | |
|---|---|---|---|---|---|
| | (Å/min) | (Å/min) | (Å/min) | (Å/min) | A-Si:TEOS |
| Polishing | 5844 | 2216 | 116 | 462 | 0.38 |
| Composition 2A | | | | | |
| (Comparative) | | | | | |
| Polishing | 4314 | 567 | 98 | 671 | 0.13 |
| Composition 2B | | | | | |
| (Inventive) | | | | | |
| Polishing | 3904 | 532 | 92 | 720 | 0.14 |
| Composition 2C | | | | | |
| (Inventive) | | | | | |
| Polishing | 2850 | 535 | 78 | 757 | 0.19 |
| Composition 2D | | | | | |
| (Inventive) | | | | | |
| Polishing | 796 | 704 | 63 | 874 | 0.88 |
| Composition 2E | | | | | |
| (Inventive) | | | | | |
| Polishing | 49 | 867 | 51 | 1033 | 17.69 |
| Composition 2F | | | | | |
| (Inventive) | | | | | |

As is apparent from the results set forth in Table 4, as the concentration of polyMADQUAT in the polishing composition was increased, the TEOS removal rate decreased. In contrast, the SiN removal rate remained relatively constant despite the variation in polyDADMAC concentration, and the A-Si and Poly removal rates increased as the concentration of polyDADMAC in the polishing composition was increased. In addition, Table 4 shows that Inventive Polishing Compositions 2E and 2F, containing 200 ppm and 500 ppm of polyMADQUAT, respectively, exhibited a significantly higher selectivity for removal of A-Si over TEOS, when compared to Comparative Polishing Composition 2A. However, changes in the concentration of polyMADQUAT did not change the removal rates of TEOS, Poly, and A-Si as significantly as did changes in the concentration of polyDADMAC, as presented in Example 1.

### Example 3

This example demonstrates the effect of the polishing pad on the polishing performance provided by a polishing composition prepared according to the invention.

Polishing Compositions 3A-3E, used in this example, were prepared by combining 2.0 wt. % surface-modified colloidal silica particles (i.e., bipodal aminosilane-modified), 0.008 wt. % acetic acid, 66.6 ppm isothiazolinone-based biocide Kordek MLX™ (DuPont, Wilmington, DE), and polyDADMAC or polyMADQUAT in the amounts set forth in Table 5, and the pH of each polishing composition was adjusted to 4.7.

TABLE 5
Polishing Compositions 3A-3E

| | Cationic |
|---|---|
| | Polymer (ppm) |
| Polishing | None |
| Composition 3A | |
| (Comparative) | |
| Polishing | polyDADMAC (40) |
| Composition 3B | |
| (Inventive) | |
| Polishing | polyDADMAC (80) |
| Composition 3C | |
| (Inventive) | |
| Polishing | polyDADMAC (120) |
| Composition 3D | |
| (Inventive) | |
| Polishing | polyMADQUAT (40) |
| Composition 3E | |
| (Inventive) | |

Wafer coupons comprising TEOS, Poly, or A-Si were each polished under identical conditions using a REFLEXION™ LK polishing machine at 3 PSI (20.55 kPa) downforce using an OPTIVISION™ 4540 pad commercially available from Pureon AG (Switzerland) conditioned with a product commercially identified as SAESOL™ CLC-S1 (SAESOL Diamond Ind. Co. Ltd.). Reflexion polishing parameters were as follows: head speed=93 rpm, platen speed=87 rpm, total flow rate=50 mL/min. Removal rates were calculated by measuring the film thickness, using spectroscopic elipsometry, and subtracting the final thickness from the initial thickness. Following polishing, the RR for TEOS, Poly, or A-Si were determined, and the results are set forth in Table 6.

TABLE 6
Polishing Removal Rates of Polishing Compositions
3A-3E with SAESOL ™ CLC-S1 Pad

| | TEOS | A-Si | Poly | |
|---|---|---|---|---|
| | (Å/min) | (Å/min) | (Å/min) | A-Si:TEOS |
| Polishing | 2782 | — | — | — |
| Composition 3A | | | | |
| (Comparative) | | | | |
| Polishing | 1686 | 532 | 553 | 0.3 |
| Composition 3B | | | | |
| (Inventive) | | | | |
| Polishing | 85 | 268 | 308 | 3.2 |
| Composition 3C | | | | |
| (Inventive) | | | | |
| Polishing | 29 | 234 | 264 | 8.1 |
| Composition 3D | | | | |
| (Inventive) | | | | |
| Polishing | 2460 | 1201 | 758 | 0.5 |
| Composition 3E | | | | |
| (Inventive) | | | | |

Similarly, wafer coupons comprising TEOS, Poly, or A-Si were each polished under identical conditions using a REFLEXION™ LK polishing machine at 3 PSI (20.55 kPa) downforce using a NEXPLANAR™ U9190 pad commercially available from CMC Materials Inc. (Aurora, IL) conditioned with a product commercially identified as A189L (3M, St. Paul, MN). Reflexion polishing parameters were as follows: head speed=93 rpm, platen speed=87 rpm, total flow rate=50 mL/min. Removal rates were calculated by measuring the film thickness, using spectroscopic elipsometry, and subtracting the final thickness from the initial thickness. Following polishing, the RR for TEOS, Poly, or A-Si were determined, and the results are set forth in Table 7.

TABLE 7
Polishing Removal Rates of Polishing Compositions
3A-3E with NEXPLANAR ™ U9190 Pad

| | TEOS | A-Si | Poly | |
|---|---|---|---|---|
| | (Å/min) | (Å/min) | (Å/min) | A-Si:TEOS |
| Polishing | 2461 | — | — | — |
| Composition 3A | | | | |
| (Comparative) | | | | |
| Polishing | 91 | 608 | 664 | 6.7 |
| Composition 3B | | | | |
| (Inventive) | | | | |
| Polishing | 25 | 305 | 332 | 12.2 |
| Composition 3C | | | | |
| (Inventive) | | | | |
| Polishing | 24 | 262 | 288 | 10.9 |
| Composition 3D | | | | |
| (Inventive) | | | | |
| Polishing | 304 | 995 | 862 | 3.3 |
| Composition 3E | | | | |
| (Inventive) | | | | |

As is apparent from the results set forth in Tables 6 and 7, the trends described in Examples 1 and 2 were generally applicable to all polishing pads and polishing machines tested. However, Tables 6 and 7 further demonstrate that the removal rates can be further fine-tuned using different polishing pads.

### Example 4

This example demonstrates the effect of cationic polymer on the polishing performance provided by a polishing composition prepared according to the invention.

Polishing Compositions 4A-4D, used in this example, were prepared by combining 2.0 wt. % surface-modified colloidal silica particles (i.e., bipodal aminosilane-modified), 0.008 wt. % acetic acid, 66.6 ppm isothiazolinone-based biocide Kordek MLX™ (DuPont, Wilmington, DE), and polyacrylamide, polyMADQUAT, polyDADMAC, and polyethylenimine (PEI) in the amounts set forth in Table 8, and the pH of each polishing composition was adjusted to 4.7.

TABLE 8
Polishing Compositions 4A-4D

| | Cationic |
|---|---|
| | Polymer (ppm) |
| Polishing | polyacrylamide (100) |
| Composition 4A | |
| (Comparative) | |
| Polishing | polyMADQUAT (100) |
| Composition 4B | |
| (Inventive) | |
| Polishing | polyDADMAC (100) |
| Composition 4C | |
| (Inventive) | |
| Polishing | PEI (100) |
| Composition 4D | |
| (Inventive) | |

Wafer coupons comprising TEOS, Poly, or A-Si were each polished under identical conditions using a Logitech benchtop polishing machine at 3 PSI (20.55 kPa) downforce using a NEXPLANAR™ E6088 pad commercially available from CMC Materials Inc. (Aurora, IL) conditioned with a product commercially identified as A189L (3M, St. Paul, MN). Logitech polishing parameters were as follows: head speed=93 rpm, platen speed=87 rpm, total flow rate=50 mL/min. Removal rates were calculated by measuring the film thickness, using spectroscopic elipsometry, and subtracting the final thickness from the initial thickness. Following polishing, the RR for TEOS, Poly, or A-Si were determined, and the results are set forth in Table 9.

TABLE 9
Polishing Removal Rates of Polishing Compositions 4A-4D

| | TEOS | A-Si | Poly | |
|---|---|---|---|---|
| | (Å/min) | (Å/min) | (Å/min) | A-Si:TEOS |
| Polishing | 4665 | 746 | 499 | 0.16 |
| Composition 4A | | | | |
| (Comparative) | | | | |
| Polishing | 3245 | 850 | 830 | 0.26 |
| Composition 4B | | | | |
| (Inventive) | | | | |
| Polishing | 565 | 1712 | 1580 | 3.03 |
| Composition 4C | | | | |
| (Inventive) | | | | |
| Polishing | 12 | 1354 | 1008 | 112.83 |
| Composition 4D | | | | |
| (Inventive) | | | | |

As is apparent from the results set forth in Table 9, Comparative Polishing Composition 4A, containing a nonionic polymer polyacrylamide, exhibited a lower selectivity for removal of A-Si over TEOS, when compared to Inventive Polishing Compositions 4B-4D, containing cationic polymers. In addition, Table 9 shows that Inventive Polishing Compositions 4C and 4D, containing polyDADMAC and PEI, respectively, exhibited significantly higher selectivity for removal of A-Si over TEOS than Comparative Polishing Composition 4A, containing polyacrylamide. The results demonstrate that the removal rates can be further fine-tuned using different cationic polymers.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical-mechanical polishing composition comprising:
(a) about 0.001 wt. % to about 10 wt. % of colloidal silica particles, wherein the colloidal silica particles are surface-modified with an aminosilane compound, and wherein the colloidal silica particles have an isoelectric point of about 6 to about 10,
(b) about 100 ppm to about 1000 ppm of a cationic polymer,
(c) a buffering agent, and
(d) water,
wherein the polishing composition has a pH of about 1 to about 6.

2. The polishing composition of claim 1, wherein the polishing composition has a pH of about 4 to about 6.

3. The polishing composition of claim 1, wherein the colloidal silica particles have an isoelectric point of about 6.5 to about 9.

4. The polishing composition of claim 1, wherein the colloidal silica particles have an average surface modification level of the aminosilane compound of from about 5% to about 50%.

5. The polishing composition of claim 1, wherein the aminosilane compound is a monopodal aminosilane compound.

6. The polishing composition of claim 1, wherein the aminosilane compound is a multipodal aminosilane compound.

7. The polishing composition of claim 1, wherein the colloidal silica particles have a zeta potential in the polishing composition of about 20 mV to about 50 mV.

8. The polishing composition of claim 1, wherein the colloidal silica particles have a D50 particle size in a range from about 30 nm to about 80 nm.

9. The polishing composition of claim 1, wherein the colloidal silica particles have an aspect ratio of greater than about 1.2.

10. The polishing composition of claim 1, wherein the colloidal silica particles have a Brunauer-Emmett-Teller (BET) surface area from about 60 m²/g to about 120 m²/g.

11. The polishing composition of claim 1, wherein the cationic polymer comprises polyethylenimine, poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly [bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof.

12. The polishing composition of claim 11, wherein the cationic polymer is poly(diallyldimethylammonium) chloride (polyDADMAC) or a salt thereof.

13. The polishing composition of claim 1, wherein the buffering agent comprises an organic acid.

14. A method of chemically-mechanically polishing a substrate comprising:
(i) providing a substrate,
(ii) providing a polishing pad,
(iii) providing a chemical-mechanical polishing composition comprising:
(a) about 0.001 wt. % to about 10 wt. % of colloidal silica particles, wherein the colloidal silica particles are surface-modified with an aminosilane compound, and wherein the colloidal silica particles have an isoelectric point of about 6 to about 10,
(b) about 100 ppm to about 1000 ppm of a cationic polymer,
(c) a buffering agent, and
(d) water,
wherein the polishing composition has a pH of about 1 to about 6,
(iv) contacting the substrate with the polishing pad and the chemical-mechanical polishing composition, and
(v) moving the polishing pad and the chemical-mechanical polishing composition relative to the substrate to abrade at least a portion of the substrate to polish the substrate.

15. The method of claim 14, wherein the colloidal silica particles have an average surface modification level of the aminosilane compound from about 5% to about 50%.

16. The method of claim 14, wherein the cationic polymer comprises polyethylenimine, poly(vinylimidazolium), polylysine, poly(methacryloyloxyethyltrimethylammonium) chloride (polyMADQUAT), poly(diallyldimethylammonium) chloride (polyDADMAC), poly(dimethylamine-co-epichlorohydrin), poly [bis(2-chloroethyl) ether-alt-1,3-bis[3-(dimethylamino)propyl]urea], copolymers of hydroxyethyl cellulose and diallyldimethylammonium, copolymers of acrylamide and diallyldimethylammonium, quaternized hydroxyethylcellulose ethoxylate, copolymers of vinylpyrrolidone and quaternized dimethylaminoethyl methacrylate, copolymers of vinylpyrrolidone and quaternized vinylimidazole, a terpolymer of vinylcaprolactam, vinylpyrrolidone, and quaternized vinylimidazole, 3-methyl-1-vinylimidazolium methyl sulfate-N-vinylpyrrolidone copolymer, copolymers of vinylpyrrolidone and diallyldimethylammonium, a salt thereof, or a combination thereof.

17. The method of claim 15, wherein the buffering agent comprises formic acid, malonic acid, acetic acid, oxalic acid, citric acid, or a combination thereof.

18. The method of claim 14, wherein the aminosilane compound is a monopodal aminosilane compound.

19. The method of claim 14, wherein the aminosilane compound is a multipodal aminosilane compound.

20. The method of claim 14, wherein the substrate comprises silicon oxide on a surface of the substrate, wherein at least a portion of the silicon oxide on a surface of the substrate is abraded at a silicon oxide removal rate (Å/min) to polish the substrate, and wherein the substrate comprises polysilicon on a surface of the substrate, wherein at least a portion of the polysilicon on a surface of the substrate is abraded at a polysilicon removal rate (Å/min) to polish the substrate, and wherein the polysilicon removal rate is greater than the silicon oxide removal rate.
